(19) United States
(12) Patent Application Publication
(10) Pub. No.: US 2024/0178252 A1
(43) Pub. Date: May 30, 2024

(54) IMAGE SENSOR

(71) Applicant: Samsung Electronics Co., Ltd., Suwon-si (KR)

(72) Inventors: Seo Joo KIM, Suwon-si (KR); Sung Hyuck CHO, Suwon-si (KR); Young Chan KIM, Suwon-si (KR); Seung Hyun LEE, Suwon-si (KR); Young Gu JIN, Suwon-si (KR)

(73) Assignee: Samsung Electronics Co., Ltd., Suwon-si (KR)

(21) Appl. No.: 18/332,270

(22) Filed: Jun. 9, 2023

(30) Foreign Application Priority Data
Nov. 24, 2022 (KR) 10-2022-0159037

(51) Int. Cl. H01L 27/146

(52) U.S. Cl. CPC H01L 27/14627; H01L 27/14603; H01L 27/14621

(57) ABSTRACT

In one embodiment, an image sensor includes unit pixels, each of the unit pixel including a first sub-pixel and a second sub-pixel adjacent to the first sub-pixel in a plan view of the image sensor; and a lens array including a first sub-lens area on the first sub-pixel of each unit pixel and a second sub-lens area on the second sub-pixel of each unit pixel. The first sub-lens area may include a first micro lens, and the second sub-lens area includes a second micro lens. In addition, the first micro lens may include a depression defined in a central area thereof.

### CROSS-REFERENCE TO RELATED APPLICATION

This application claims priority from Korean Patent Application No. 10-2022-0159037 filed on Nov. 24, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to image sensors.

### Description of Related Art

An image sensing device senses an image using an optical sensor. The image sensing device includes an image sensor. One type of the image sensor is a CMOS image sensor. The CMOS image sensor may include a plurality of pixels disposed two-dimensionally. Each of the pixels may include a photodiode. The photodiode may serve to convert incident light thereto into an electrical signal.

Recently, under development of the computer industry and the communication industry, demand for image sensors with improved performance is increasing in various fields such as digital cameras, camcorders, smartphones, game devices, security cameras, medical micro cameras, robots, and vehicles, etc.

### SUMMARY

A purpose of the present disclosure is to provide image sensors with improved image quality.

Purposes according to the present disclosure are not limited to the above-mentioned purpose. Other purposes and advantages according to the present disclosure that are not mentioned may be understood based on following descriptions, and may be more clearly understood based on example embodiments according to the present disclosure. Further, it will be easily understood that the purposes and advantages according to the present disclosure may be realized using means shown in the claims and combinations thereof.

According to some aspects of the present disclosure, there is provided an image sensor comprising unit pixels, each unit pixel including a first sub-pixel and a second sub-pixel adjacent to the first sub-pixel in a plan view of the image sensor; and a lens array including a first sub-lens area on the first sub-pixel of each unit pixel and a second sub-lens area on the second sub-pixel of each unit pixel. The first sub-lens area may include a first micro lens, and the second sub-lens area includes a second micro lens. In addition, the first micro lens may include a depression defined in a central area thereof.

According to some aspects of the present disclosure, there is provided an image sensor comprising a plurality of unit pixels, each unit pixel including a first sub-pixel and a second sub-pixel adjacent to the first sub-pixel in a plan view of the image sensor, an area size of a second sub-pixel being smaller than an area size of the first sub-pixel in the plan view; and a lens array including a first sub-lens area on the first sub-pixel of each unit pixel and a second sub-lens area on the second sub-pixel of each unit pixel. The first sub-lens area may include a first micro lens, and the second sub-lens area includes a second micro lens. In addition, a first width of a first cross section of the first micro lens cut along a direction toward the second sub-pixel may be smaller than a second width of a second cross section of the first micro lens cut along a direction toward another first micro lens adjacent thereto.

According to some aspects of the present disclosure, there is provided an image sensor comprising a plurality of unit pixels, each unit pixel including a first sub-pixel and a second sub-pixel adjacent to the first sub-pixel in a plan view of the image sensor, an area size of a second sub-pixel being smaller than an area size of the first sub-pixel in the plan view; and a lens array including a first sub-lens area on the first sub-pixel of each unit pixel and a second sub-lens area on the second sub-pixel of each unit pixel. The first sub-lens area may include a plurality of first micro lenses, and the second sub-lens area includes a second micro lens. In addition, a number of the second micro lenses included in the second sub-lens area may be smaller than a number of the plurality of first micro lenses included in the first sub-lens area.

Specific details of example embodiments are included in detailed descriptions and drawings.

### BRIEF DESCRIPTION OF DRAWINGS

The above and other aspects and features of the present disclosure will become more apparent by describing in detail illustrative example embodiments thereof with reference to the attached drawings, in which:

FIG. 1 is a block diagram of an image sensing device according to some example embodiments.

FIG. 2 is a schematic perspective view showing a stack structure of an image sensor according to some example embodiments.

FIG. 3 is a schematic perspective view showing a stack structure of an image sensor according to some example embodiments.

FIG. 4 is a block diagram of an image sensor according to some example embodiments.

FIG. 5 is a schematic exploded perspective view of an image sensor according to some example embodiments.

FIG. 6 is an illustrative circuit diagram of one pixel in FIG. 5.

FIG. 7 is an illustrative timing diagram for illustrating an operation of one pixel having a circuit structure of FIG. 6.

FIG. 8 is a graph showing a signal-to-noise ratio based on an illuminance of a pixel under a pixel operation of FIG. 7.

FIG. 9 is a cross-sectional view of a pixel according to some example embodiments, and shows a cross-sectional shape cut along a line X-X′ in FIG. 5.

FIG. 10 to FIG. 13 are respective schematic diagrams showing light paths through lens arrays according to some example embodiments.

FIG. 14 is a cross-sectional view of a lens array according to some example embodiments.

FIG. 15 is a cross-sectional view of a lens array according to some example embodiments.

FIG. 16 is a cross-sectional view of a lens array according to some example embodiments.

FIG. 17 is a cross-sectional view of a lens array according to some example embodiments.

FIG. 18 is a cross-sectional view of a lens array according to some example embodiments.

FIG. 19 is a plan layout diagram of an image sensor according to some example embodiments.

FIG. 20 is a cross-sectional view taken along a line XX-XX′ in FIG. 19.

FIG. 21 is a plan layout diagram of an image sensor according to some example embodiments.

FIG. 22 is a cross-sectional view taken along each of lines XXIIa-XXIIa′ and XXIIb-XXIIb′ of FIG. 21.

FIG. 23 is a plan layout diagram of an image sensor according to some example embodiments.

FIG. 24 is a cross-sectional view taken along each of lines XXIVa-XXIVa′ and XXIVb-XXIVb′ in FIG. 23.

FIG. 25 is a plan layout diagram of an image sensor according to some example embodiments.

FIG. 26 is a cross-sectional view taken along each of lines XXVI-XXVI′ in FIG. 25.

FIG. 27 is a plan layout diagram of an image sensor according to some example embodiments.

FIG. 28 is a cross-sectional view taken along each of lines XXVIII-XXVIII′ of FIG. 27.

FIG. 29 is a plan layout diagram of an image sensor according to some example embodiments.

FIG. 30 is a cross-sectional view taken along an XXX-XXX′ line in FIG. 29.

FIG. 31 is a plan layout diagram of an image sensor according to some example embodiments.

FIG. 32 is a cross-sectional view taken along an XXXII-XXXII′ line in FIG. 31.

FIG. 33 is a graph showing a simulation result of light receiving efficiency of the second micro lens based on a viewing angle of each of lens arrays according to some example embodiments.

### DETAILED DESCRIPTIONS

Hereinafter, example embodiments according to the technical idea of the present disclosure will be described with reference to the accompanying drawings.

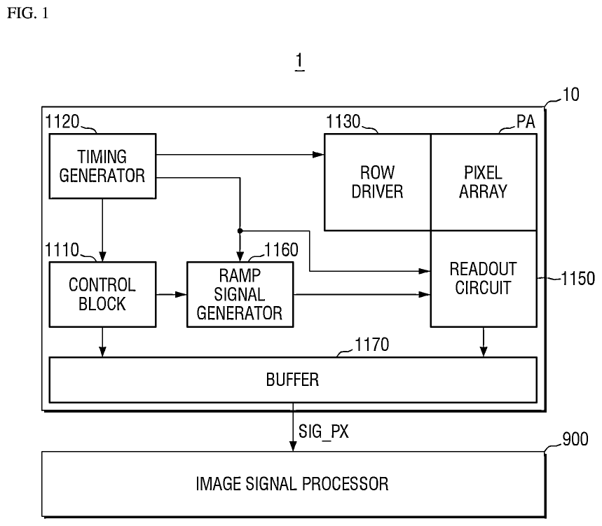

FIG. 1 is a block diagram of an image sensing device according to some example embodiments.

Referring to FIG. 1, an image sensing device 1 may include an image sensor 10 and an image signal processor 900.

The image sensor 10 may sense an image of a sensing target using light, and may generate a pixel signal SIG_PX based on the sensed image. The generated pixel signal SIG_PX may be, for example, a digital signal. However, the present disclosure is not limited thereto. Further, the pixel signal SIG_PX may include specific signal voltage or reset voltage, etc. The pixel signal SIG_PX may be provided to and processed by the image signal processor 900.

The image sensor 10 may include a control register block 1110, a timing generator 1120, a row driver 1130, a pixel array PA, a readout circuit 1150, a ramp signal generator 1160, and a buffer 1170.

The control register block 1110 may control all operations of the image sensor 10. The control register block 1110 may send an operation control signal directly to the timing generator 1120, the ramp signal generator 1160 and the buffer 1170.

The timing generator 1120 may generate an operation timing reference signal as a reference for an operation timing of each of the various components of the image sensor 10. The operation timing reference signal generated from the timing generator 1120 may be transmitted to the row driver 1130, the readout circuit 1150, the ramp signal generator 1160, and the like.

The ramp signal generator 1160 may generate and transmit a ramp signal to be used in the readout circuit 1150. The readout circuit 1150 may include a correlated double sampler (CDS), a comparator, etc. The ramp signal generator 1160 may generate and transmit the ramp signal to be used in the CDS, the comparator, and the like.

The buffer 1170 may temporarily store therein the pixel signal SIG_PX to be provided to an external component, and may serve to transmit the pixel signal SIG_PX to an external memory or an external device. The buffer 1170 may include a memory such as DRAM or SRAM.

The pixel array PA may sense an external image. The pixel array PA may include a plurality of pixels PX (or, alternatively, a unit pixel PX). The row driver 1130 may selectively activate a row of the pixel array PA.

The readout circuit 1150 may sample the pixel signal (e.g., an analog image signal) provided from the pixel array PA, may compare the sampled pixel signal with the ramp signal, and may convert an analog image signal (analog data) into a digital image signal (digital data) based on the comparison result.

The image signal processor 900 may receive the pixel signal SIG_PX output from the buffer 1170 of the image sensor 10 and may process the received pixel signal SIG_PX for display thereof. The image signal processor 900 may be physically spaced from the image sensor 10. For example, the image sensor 10 may be mounted into a first chip while the image signal processor 900 may be mounted into a second chip. The image signal processor 900 and the image sensor 10 may communicate with each other through a predefined (or, alternatively, desired, selected, etc.) interface. However, example embodiments are not limited thereto, and the image sensor 10 and the image signal processor 900 may be implemented into one package, for example, an MCP (multi-chip package).

As described above, the image sensor may be embodied as a single chip. For example, all the functional blocks as described above may be implemented in one chip. However, example embodiments are not limited thereto, and the functional blocks may be distributed across a plurality of chips. When the image sensor is embodied as a plurality of chips, the chips may be stacked. Hereinafter, an example in which the image sensor is embodied as the stack of the chips will be described.

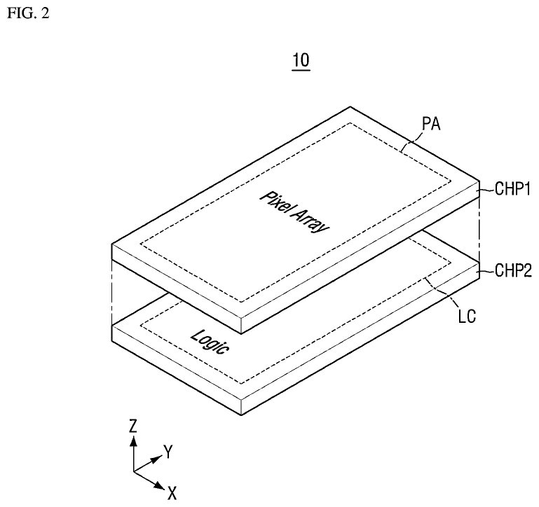

FIG. 2 is a schematic perspective view showing a stack structure of an image sensor according to some example embodiments. In FIG. 2, a first direction X, a second direction Y, and a third direction Z are defined. The first direction X, the second direction Y and the third direction Z intersect each other. For example, the first direction X, the second direction Y, and the third direction Z may intersect each other perpendicularly. Each of the first direction X and the second direction Y may be a horizontal direction, and the third direction Z may be a vertical direction. The third direction Z may be a thickness direction and/or a depth direction of the device.

Referring to FIG. 2, the image sensor 10 may include a stack of an upper chip CHP1 and a lower chip CHP2. The upper chip CHP1 may include the pixel array PA. The lower chip CHP2 may include an analog area and a logic area LC including the readout circuit 1150. The lower chip CHP2 may be disposed below the upper chip CHP1, and may be electrically connected to the upper chip CHP1. The lower chip CHP2 may receive the pixel signal from the upper chip CHP1. The logic area LC may receive the corresponding pixel signal.

Logic elements may be disposed in the logic area LC of the lower chip CHP2. The logic elements may include circuits for processing the pixel signal from the pixels PX. For example, the logic elements may include the control register block 1110, the timing generator 1120, the row driver 1130, the readout circuit 1150, the ramp signal generator 1160, and/or the like.

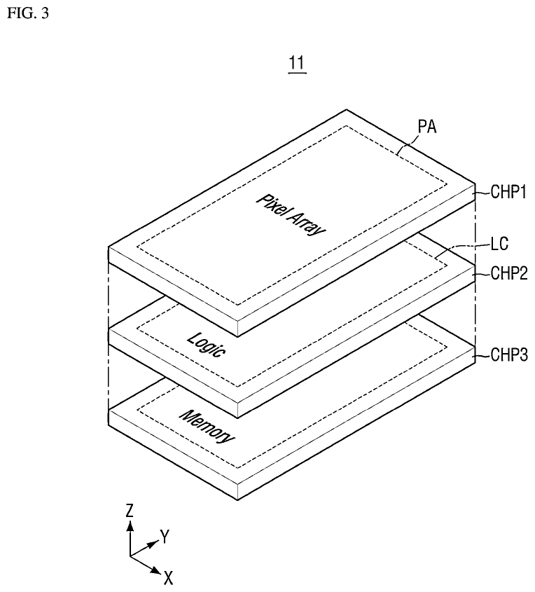

FIG. 3 is a schematic perspective view showing a stack structure of an image sensor according to some example embodiments. Some example embodiments of FIG. 3 are different from some example embodiments of FIG. 2 in that an image sensor 11 of FIG. 3 further includes a memory chip CHP3.

Specifically, as shown in FIG. 3, the image sensor 11 may include the upper chip CHP1, the lower chip CHP2, and the memory chip CHP3. The upper chip CHP1, the lower chip CHP2, and the memory chip CHP3 may be sequentially stacked along the third direction Z. The memory chip CHP3 may be disposed below the lower chip CHP2. The memory chip CHP3 may include a memory device. For example, the memory chip CHP3 may include a volatile memory device such as DRAM or SRAM. The memory chip CHP3 may receive a signal from the upper chip CHP1 and the lower chip CHP2 and may process the signal using the memory device. The image sensor 11 including the memory chip CHP3 may act as a 3-stack image sensor.

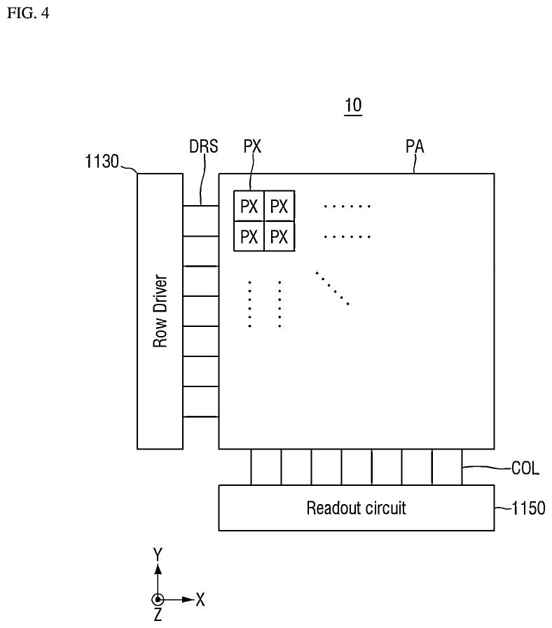

Hereinafter, a pixel structure of the image sensor will be described in more detail. FIG. 4 is a block diagram of an image sensor according to some example embodiments.

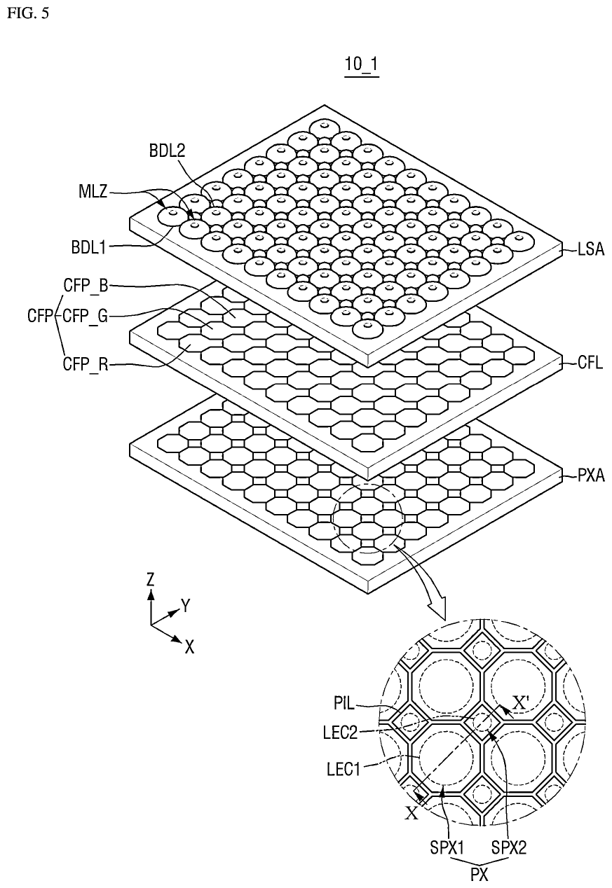

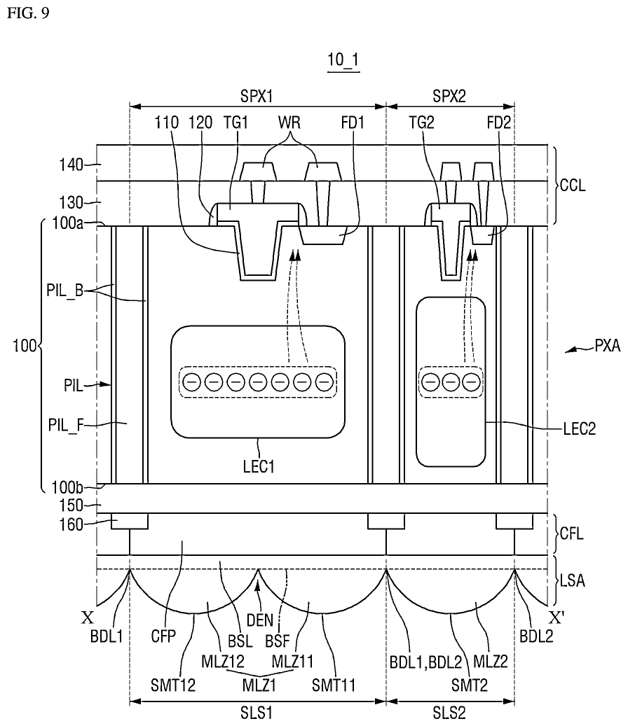

Referring to FIG. 4, the pixel array PA may include a plurality of pixels PX. The pixel PX may be a basic sensing unit that receives light and outputs an image corresponding to one pixel PX. Each pixel PX may include a plurality of sub-pixels (e.g., SPX1 and SPX2 in FIG. 5). Each of the sub-pixels SPX1 and SPX2 may have a photoelectric converter (e.g., LEC1 and LEC2 in FIG. 9).

The plurality of pixels PX may be disposed in a two-dimensional matrix having a plurality of rows and a plurality of columns. For convenience of description, a row refers to an array extending in the first direction X and a column refers to an array extending in the second direction Y in FIG. 4. However, the present disclosure is not limited thereto. A row refers to an array extending in the second direction Y and a column refers to an array extending in the first direction X in FIG. 4. Although a case where the rows and the columns intersect each other in a rectangular matrix manner is illustrated in the drawing, an arrangement shape of the pixels PX may be variously modified. For example, the row or the column may extend in a zigzag manner rather than a straight line, or pixels PXs disposed in adjacent rows/columns may be disposed in a staggered manner.

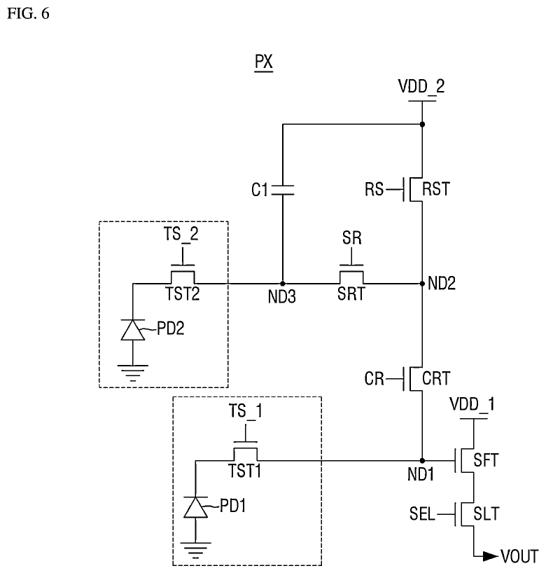

A plurality of drive signal lines DRS are connected to the row driver 1130. The plurality of drive signal lines DRS may extend along a row extension direction, that is, the first direction X. The plurality of drive signal lines DRS may extend, in the first direction X, across an active area of the pixel array PA as an effective area in which the pixels PX are disposed. The plurality of drive signal lines DRS may transmit a drive signal provided from the row driver to the pixels PX. The drive signal may include, for example, a select signal (e.g., SEL in FIG. 6), a reset signal (e.g., RG in FIG. 6), a transfer signal (e.g., TS1 and TS2 in FIG. 6), and the like.

In some example embodiments, the pixels PX disposed in the same row may be connected to the same drive signal line DRS. Alternatively, the pixels PX disposed in different rows may be connected to different drive signal lines DRS. However, some example embodiments is not limited thereto, and the pixels PX disposed in the same row may be connected to different drive signal lines DRS, or the pixels PX disposed in two or more different rows may be connected to the same drive signal line DRS.

A plurality of output signal lines COL may be connected to the readout circuit 1150. The plurality of output signal lines COL may extend along a column extension direction, that is, the second direction Y. The plurality of output signal lines COL may extend across the active area of the pixel array PA in the second direction Y. The plurality of output signal lines COL may transmit an output signal provided from the pixels PX to the readout circuit 1150.

In some example embodiments, the pixels PX disposed in the same column may be connected to the same output signal line COL. Alternatively, the pixels PX disposed in different columns may be connected to different output signal lines COL. However, some example embodiments is not limited thereto, and pixels PX disposed in the same column may be connected to different output signal lines COL, or pixels PX disposed in two or more different columns may be connected to the same output signal line COL.

FIG. 5 is a schematic exploded perspective view of an image sensor according to some example embodiments.

Referring to FIG. 5, an image sensor 10_1 may include a pixel array PXA and a lens array LSA. The lens array LSA may be disposed on a light incident face of the pixel array PXA. A color filter layer CFL may be disposed between the pixel array PXA and the lens array LSA.

A plurality of pixels PX are defined in the pixel array PXA. The plurality of pixels PX may be arranged in a matrix shape. Each pixel PX may include a photoelectric converter LEC constituting a photodiode.

One pixel PX may be split into two or more sub-pixels. That is, one pixel PX may include a plurality of sub-pixels SPX1 and SPX2. For example, one pixel PX may include two or more sub-pixels SPX1 and SPX2. In some example embodiments as illustrated in the drawing, each of the pixels PX includes the first sub-pixel SPX1 and the second sub-pixel SPX2. The first sub-pixel SPX1 and the second sub-pixel SPX1 belonging to one pixel PX may be disposed adjacent to each other. In some example embodiments, the first sub-pixel SPX1 may have an octagonal shape, and the second sub-pixel SPX2 may have a quadrangular shape. The second sub-pixel SPX2 may be disposed adjacent to one of eight edges of the first sub-pixel SPX1. One edge of the first sub-pixel SPX1 and one edge of the second sub-pixel SPX2 may contact each other. However, the present disclosure is not limited thereto.

In some example embodiments, a plurality of first sub-pixels SPX1 may be arranged so as to be adjacent to each other along each of the first direction X and the second direction Y, while the first sub-pixels SPX1 and the second sub-pixels SPX2 may be alternately arranged with each other and adjacent to each other along a diagonal direction intersecting the first direction X and the second direction Y.

The first sub-pixel SPX1 may include a first photoelectric converter LEC1 constituting a first photodiode PD1. The second sub-pixel SPX2 may include a second photoelectric converter LEC2 constituting a second photodiode PD2.

The first sub-pixel SPX1 and the second sub-pixel SPX2 may have different full well capacities. For example, the first sub-pixel SPX1 may have a greater full well capacity than that of the second sub-pixel SPX2. In some example embodiments, in a plan view, the first sub-pixel SPX1 has a larger size (or area) than that of the second sub-pixel SPX2, and thus the first photoelectric converter LEC1 may also be larger than the second photoelectric converter LEC2. Thus, when the first sub-pixel SPX1 has a larger size in a plan view than that of the second sub-pixel SPX2, the former has a larger amount of light reception, and thus may advantageously sense a light amount at relatively low luminance. Conversely, the second sub-pixel SPX2 may be mainly used for sensing a light amount at relatively high luminance. In this way, a larger dynamic range may be implemented by operating the first sub-pixel SPX1 and the second sub-pixel SPX2 so as to sense the light amount appropriately.

The photoelectric converters LEC1 and LEC2 of each pixel PX may be isolated from each other via an element isolation film PIL. Further, the element isolation film PIL that prevents or reduces electric charge drift between the first sub-pixel SPX1 and the second sub-pixel SPX2 may be disposed therebetween. That is, the element isolation film PIL may have a layout shape enclosing each of the plurality of first sub-pixels SPX1 and the plurality of second sub-pixels SPX2 in a plan view. In some example embodiments, the element isolation film PIL partitioning each of the sub-pixels SPX1 and SPX2 into a plurality of areas may not be disposed in each of the sub-pixels SPX1 and SPX2. That is, each of the first photoelectric converter LEC1 and the second photoelectric converter LEC2 may not be discontinuous but may be an integral area.

The element isolation film PIL may be provided in a form of STI (shallow trench isolation), DTI (deep trench isolation), or the like. When the element isolation film PIL is provided in a form of the DTI, the element isolation film PIL may be applied to a FSI (frontside illuminated) type image sensor, or may be applied to a FDTI (front deep trench isolation) type image sensor extending in a vertical direction from one face of a semiconductor substrate, or to a BSI (backside illuminated type) type image sensor, or may be applied to a BDTI (back deep trench isolation) type extending in a vertical direction from the other face of the semiconductor substrate.

A shape, a material, and a stacking structure of the element isolation film PIL may be the same regardless of an area thereof. However, the present disclosure is not limited thereto. For example, one partial area of the element isolation film PIL may have a different isolation structure from that of the other partial area thereof.

The image sensor 10_1 may sense a color of incident light in a distinguishing manner. In this case, the image sensor 10_1 may include a color filter layer CFL. The color filter layer CFL may be disposed on the light incident face of the pixel array PXA. The color filter layer CFL may include a plurality of color filter patterns CFP. For example, the color filter layer CFL may include a red color filter pattern CFP_R, a green color filter pattern CFP_G, and a blue color filter pattern CFP_B.

Each color filter pattern CFP may correspond to the pixel PX. One pixel PX may correspond to a color filter pattern CFP of the same color. For example, one of the red color filter pattern CFP_R, the green color filter pattern CFP_G, or the blue color filter pattern CFP_B may be disposed on the first sub-pixel SPX1 and the second sub-pixel SPX2 included in one pixel PX. The color filter patterns CFP corresponding to and disposed on the first sub-pixel SPX1 and the second sub-pixel SPX2 included in one pixel PX may be a single pattern connected to each other as shown, or may be separated patterns corresponding to the first and second sub-pixels. Even when the color filter patterns CFP are separated from each other in a corresponding manner to the first and second sub-pixels, the colors of the color filter patterns CFP may be equal to each other.

The lens array LSA may be disposed on the color filter layer CFL. The lens array LSA may include a plurality of micro lenses MLZ. The micro lens MLZ may condense incident light to prevent or reduce color mixing and increase light efficiency. Each of the plurality of micro lenses MLZ may be disposed to cover a partial area of each pixel PX. A detailed description of the lens array LSA will be set forth later.

FIG. 6 is an illustrative circuit diagram of one pixel in FIG. 5.

Referring to FIG. 6, a circuit of one pixel PX includes the first photodiode PD1, the second photodiode PD2, a plurality of transistors, and a capacitor C1. The plurality of transistors may include a transfer transistor TST, a source follower transistor SFT, a select transistor SLT, a rest transistor RST, a connection transistor CRT, and a switching transistor SRT. The transfer transistor TST may include a first transfer transistor TST1 and a second transfer transistor TST2.

The first sub-pixel SPX1 may include the first photodiode PD1 and the first transfer transistor TST1, and the second sub-pixel SPX2 may include the second photodiode PD2 and the second transfer transistor TST2. The first photodiode PD1 may correspond to the first photoelectric conversion area LEC1, and the second photodiode PD2 may correspond to the second photoelectric conversion area LEC2. The first photodiode PD1 including the first photoelectric conversion area LEC1 which has a relatively larger area in the plan view may be referred to as a large photodiode, while the second photodiode PD2 including the second photoelectric conversion area LEC2 which has a relatively smaller area in the plan view may be referred to as a small photodiode.

The first sub-pixel SPX1 and the second sub-pixel SPX2 may share one source follower transistor SFT, one select transistor SLT and one rest transistor RST with each other.

More specifically, the first transfer transistor TST1 is disposed between the first photodiode PD1 and a first node ND1. The first node ND1 may be connected to a first floating diffusion area FD1, or the first node ND1 itself may act as the first floating diffusion area FD1. A gate of the first transfer transistor TST1 may be connected to a first transfer line and may receive a first transfer signal TS_1 therefrom.

The source follower transistor SFT is disposed between and connected to a first power voltage line providing a first power voltage VDD_1 and an output signal line COL. A gate of the source follower transistor SFT is connected to the first node ND1 connected to the first floating diffusion area FD1.

The select transistor SLT is disposed between the source follower transistor SFT and the output signal line COL. A gate of the select transistor SLT may be connected to a select line of a corresponding row and may receive a select signal SEL therefrom.

The connection transistor CRT and the rest transistor RST are disposed between the first node ND1 and a second power voltage line providing a second power voltage VDD_2. A second node ND2 is defined between the connection transistor CRT and the rest transistor RST.

The connection transistor CRT is disposed between the first node ND1 and the second node ND2. A gate of the connection transistor CRT is connected to a connection signal line. The connection transistor CRT may serve to connect the first node ND1 and the second node ND2 to each other based on a connection control signal CR provided from the connection signal line.

The rest transistor RST is disposed between the second power voltage line and the second node ND2. A gate of the rest transistor RST may be connected to a rest line and may receive a rest signal RS therefrom.

The second transfer transistor TST2 and the switching transistor SRT are disposed between the second photodiode PD2 and the second node ND2. A third node ND3 is defined between the second transfer transistor TST2 and the switching transistor SRT.

The second transfer transistor TST2 is disposed between and connected to the second photodiode PD2 and the third node ND3. The third node ND3 may be connected to a second floating diffusion area FD2 or the third node ND3 itself may act as the second floating diffusion area FD2. A gate of the second transfer transistor TST2 may be connected to a second transfer line. The second transfer line may receive a second transfer signal TS_2 as a scan signal different from that a first transfer signal from the first transfer line. Accordingly, the first transfer transistor TST1 and the second transfer transistor TST2 may be turned on and off at different times.

The switching transistor SRT is disposed between the third node ND3 and the second node ND2. A gate of the switching transistor SRT is connected to a switch control line. The switching transistor SRT may serve to connect the third node ND3 and the second node ND2 to each other based on a switch control signal SR applied thereto via the switch control line.

The capacitor C1 is disposed between the third node ND3 and the second power voltage line. The capacitor C1 may serve to store therein electric charges overflowing from the second photodiode PD2.

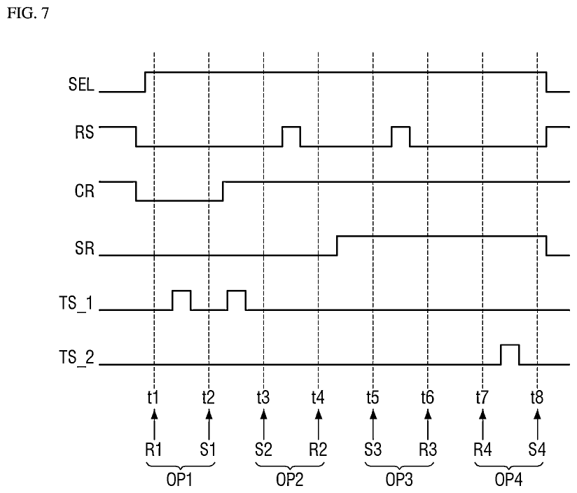

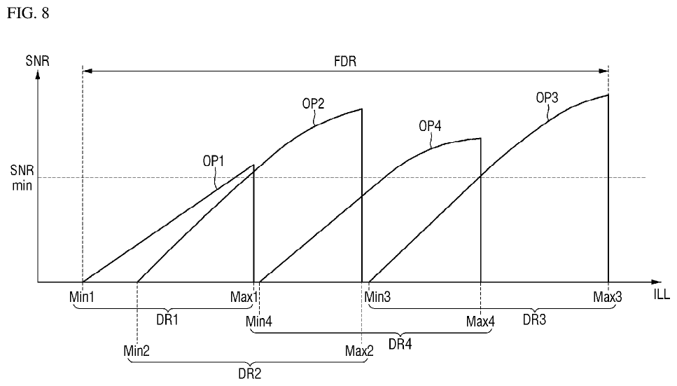

FIG. 7 is an illustrative timing diagram for illustrating an operation of one pixel having a circuit structure of FIG. 6. FIG. 8 is a graph showing a signal-to-noise ratio based on an illuminance of a pixel under a pixel operation of FIG. 7.

FIG. 7 shows a timing of a signal applied to one pixel PX positioned in a row as selected as a read-out target at a corresponding time-point. At the same time-point as the corresponding time-point, signals different from those as shown in the illustrated example may be applied to pixels PX corresponding to other rows not selected as the read-out target. For example, signal waveforms occurring before or after four operations OP1, OP2, OP3, and OP4 in FIG. 7 may be applied to the pixels PX corresponding to other rows not selected as the read-out target. In the timing diagram of FIG. 7, waveforms of the select signal SEL, the rest signal RS, the connection control signal CR, the switch control signal SR, the first transfer signal TS_1, and the second transfer signal TS_2 are shown in this order. Each of the signal waveforms swings between a high level voltage and a low level voltage. The high level voltage may be a turn-on signal for turning on a transistor receiving the same, while the low level voltage may be a turn-off signal for turning off a transistor receiving the same.

Referring to FIG. 6 to FIG. 8, an read-out operation of the pixel PX may include four operations. Specifically, the read-out operation of the pixel PX may include a first operation OP1, a second operation OP2, a third operation OP3, and a fourth operation OP4, which are sequentially performed in a temporal order. The operations OP1 to OP4 may respectively include signal operations S1, S2, S3, and S4, and may further respectively include rest operations R1, R2, R3, and R4. In each of the operations OP1 to OP4, the rest operation may be performed before or after the signal operation. In each of some of the operations OP1 to OP4, the rest operations may be omitted. During the four operations, the select signal SEL is maintained at a high level.

For a time duration before the read-out, that is, for a time duration before the first operation OP1, each of the select signal SEL, the switch control signal SR, the first transfer signal TS_1 and the second transfer signal TS_2 is maintained at a low level, and each of the rest signal RS and the connection control signal CR is maintained at a high level.

In the first operation OP1, the first rest operation R1 may be first performed at a first time t1, and then the first signal operation S1 may be performed at a second time t2.

Specifically, the select signal SEL is converted from a low level to a high level, and each of the rest signal RS and the switch control signal SR is converted from a high level to a low level by the first time t1 when the first rest operation R1 is performed. During the first rest operation R1, the charges accumulated in the first node ND1 may be converted to a first reset voltage VR1 via the source follower transistor SFT and then the first reset voltage VR1 may be output.

Subsequently, the first signal operation S1 may be performed at the second time t2. For a time period between the first time t1 and the second time t2, the first transfer signal TS_1 may be switched from a low-level to a high-level and then switched back to a low-level. While the first transfer signal TS_1 is maintained at a high-level, the first transfer transistor TST1 may be turned on for a predetermined (or, alternatively, desired, selected, etc.) time duration and then turned off. While the first transfer transistor TST1 is turned on, the first node ND1 may be connected to the first photodiode PD1. Thus, the charges stored in the first photodiode PD1 may be transferred to the first node ND1, that is, the first floating diffusion area FD1. The charges transferred to the first node ND1 may be converted into the first signal voltage VS1 via the source follower transistor SFT and then the first signal voltage VS1 may be output.

In the first operation OP1 which outputs the electric charges generated from the first photodiode PD1 and delivered to the first node ND1, the pixel PX has a relatively small capacitance, so that a first dynamic range DR1 of the first operation OP1 has a dynamic range of a low luminance as shown in FIG. 8. Therefore, the first operation OP1 may be usefully used for image sensing in a low luminance environment.

After the first operation OP1, the second operation OP2 is performed. In the second operation OP2, a second signal operation S2 may be first performed at a third time t3, and then a second reset operation R2 may be performed at a fourth time t4.

Specifically, for a time period between the second time t2 and the third time t3, the connection control signal CR is switched from a low-level to a high-level to turn on the connection transistor CRT. As a result, the first node ND1 and the second node ND2 may be connected to each other.

Further, for a time period between the second time t2 and the third time t3, the first transfer signal TS_1 may be switched from a low-level to a high-level and then switched back to a low-level while the connection transistor CRT is turned on. While the connection transistor CRT and the first transfer transistor TST1 are simultaneously turned on, the first node ND1 may be connected to the first photodiode PD1 and the second node ND2. Accordingly, for this time duration, charges of the first photodiode PD1 and the second node ND2 may be transferred to the first node ND1. The electric charges transferred to the first node ND1 may be converted into a second signal voltage VS2 via the source follower transistor SFT and then the second signal voltage VS2 may be output.

Subsequently, the second reset operation R2 may be performed at the fourth time t4. For a time period between the third time t3 and the fourth time t4, the reset signal RS may be switched from a low-level to a high-level and then switched back to a low-level. While the reset signal RS is maintained at a high-level, the reset transistor RST may be turned on, and the charges of the first node ND1 and the second node ND2 may be reset. The reset charges of the first node ND1 and the second node ND2 may be converted into a second reset voltage VR2 via the source follower transistor SFT and then the second reset voltage VR2 may be output.

In the second operation OP2, the first node ND1 and the second node ND2 are connected to each other, such that the pixel PX may have a larger capacitance than that in the first operation OP1. Therefore, a second dynamic range DR2 of the second operation OP2 has a larger value than that of the first dynamic range DR1, as shown in FIG. 8. The second dynamic range DR2 may partially overlap the first dynamic range DR1 and may have a greater maximum signal-to-noise value SNR than that of the first dynamic range DR1.

After the second operation OP2, the third operation OP3 is performed. In the third operation OP3, a third signal operation S3 may be first performed at a fifth time t5, and then a third reset operation R3 may be performed at a sixth time t6.

Specifically, for a time period between the fourth time t4 and the fifth time t5, the switch control signal SR is switched from a low-level to a high-level to turn on the switching transistor SRT. As a result, and the second node ND2 and the third node ND3 connected to capacitor C1 may be connected to each other. That is, for this time duration, all of the first node ND1, the second node ND2, and the third node ND3 may be connected to each other, and the charges accumulated therein may be converted into a third signal voltage VS3 via the source follower transistor SFT and then the third signal voltage VS3 may be output. The third signal voltage VS3 may include an output corresponding to the charges accumulated in the capacitor C1.

Subsequently, the third reset operation R3 may be performed at the sixth time t6. During a time duration between the fifth time t5 and the sixth time t6, the reset signal RS may be switched from a low-level to a high-level and then switched back to a low-level. While the reset signal RS is maintained at a high-level, the reset transistor RST is turned on, and charges of the first node ND1, the second node ND2, and the third node ND3 may be reset. The reset charges of the first node ND1, the second node ND2, and the third node ND3 may be converted to a third reset voltage VR3 via the source follower transistor SFT and then the third reset voltage VR3 may be output.

In the third operation OP3, not only the first node ND1 and the second node ND2 are connected to each other, but also the third node ND3 to which the capacitor C1 with large capacitance is connected is connected thereto, such that the pixel PX may have a larger full well capacity that in the second operation OP2. Accordingly, as shown in FIG. 8, the third operation OP3 may have a third dynamic range DR3 larger than the second dynamic range DR2. The third dynamic range DR3 may not overlap with the second dynamic range DR2. That is, a minimum luminance Min3 of the third dynamic range DR3 may be greater than a maximum luminance Max2 of the second dynamic range DR2.

The third dynamic range DR3 implemented by the third operation OP3 may be usefully used for image sensing in a high luminance environment. The third dynamic range DR3 may have a greater maximum signal-to-noise value SNR than that of the second dynamic range DR2.

After the third operation OP3, the fourth operation OP4 is performed. In the fourth operation OP4, a fourth reset operation R4 may be first performed at a seventh time t7, and then a fourth signal operation S4 may be performed at an eighth time t8.

The fourth reset operation R4 may be performed without changing an applied signal. That is, for a time period between the sixth time t6 and the seventh time t7, the signal may not be changed. The electric charges accumulated in the first node ND1, the second node ND2, and the third node ND3 may be converted to a fourth reset voltage VR4 via the source follower transistor SFT and then the fourth reset voltage VR4 may be output.

In some example embodiments, the fourth reset operation R4 may be omitted. When the fourth reset operation R4 is omitted, the third reset voltage VR3 generated in the third reset operation R3 may be used as a reference voltage.

Subsequently, the fourth signal operation S4 is performed at the eighth time t8. For a time period between the seventh time t7 and the eighth time t8, the second transfer signal TS_2 may be switched from a low-level to a high-level and then switched back to a low-level. While the second transfer signal TS_2 is maintained at a high-level, the second transfer transistor TST2 may be turned on so that the third node ND3 may be connected to the second photodiode PD2. Thus, the charges stored in the second photodiode PD2 may be transferred to the third node ND3, that is, the second floating diffusion area FD2. At this point, the third node ND3 is connected to the second node ND2 and the first node ND1, so that the charges transferred to the third node from the second photodiode PD2 together with the charges previously accumulated in the third node ND3 and the second node ND2 are transferred to the first node ND1. Then, the charges transferred to the first node ND1 may be converted to a fourth signal voltage VS1 via the source follower transistor SFT and then the fourth signal voltage VS1 may be output.

The fourth operation OP4 outputs the electric charges generated from the second photodiode PD2 and transferred to the third node ND3. In the fourth operation OP4, the first node ND1, the second node ND2, and the third node ND3 are connected to each other as in the third operation OP3. However, the fourth operation OP4 is performed after the read-out by the capacitor C1 connected to the third node ND3 has been completed, and rest, such that the fourth operation OP4 has a fourth dynamic range DR4 smaller than the third dynamic range DR3, as shown in FIG. 8. The fourth dynamic range DR4 may be positioned between the second dynamic range DR2 and the third dynamic range DR3. A minimum luminance Min4 of the fourth dynamic range DR4 may be smaller than the maximum luminance Max2 of the second dynamic range DR2 but may be greater than the maximum luminance Mini of the first dynamic range DR1. A maximum luminance Max4 of the fourth dynamic range DR4 may be larger than the minimum luminance Min3 of the third dynamic range DR3 and may be smaller than the maximum luminance Max3 thereof. A maximum signal-to-noise value SNR of the fourth dynamic range DR4 may be larger than the maximum signal-to-noise value SNR of the first dynamic range DR1 and may be smaller than the maximum signal-to-noise value SNR of the second dynamic range DR2. However, the present disclosure is not limited thereto.

In this way, when the pixel PX has the first photodiode PD1 and the second photodiode PD2 of different sizes, a dynamic range DR of various ranges may be set by diversifying a connection relationship between the nodes. Therefore, since the pixel PX may output a signal having a full dynamic range FDR including the first to fourth dynamic ranges DR1, DR2, DR3, and DR4, the full well capacity of the image sensor 10_1 may increase. In addition, as the plurality of dynamic ranges are set to partially overlap each other, an output greater than or equal to a reference signal-to-noise ratio SNRmin as a minimum reference as required in a wide luminance range may be obtained, such that image sensing quality may be improved.

After the fourth operation OP4, each of the select signal SEL and the switch control signal SR may be switched from a high-level to a low-level, and the reset signal RS may be switched from a low-level to a high-level.

FIG. 9 is a cross-sectional view of a pixel according to some example embodiments, and shows a cross-sectional shape cut along a line X-X′ in FIG. 5.

In FIG. 9, for convenience, the lens array LSA is shown as being disposed under the pixel array PXA. However, a vertical positional relationship between the lens array LSA and the pixel array PXA may vary depending on a direction in which the pixel PX is viewed.

The pixel array PXA includes a substrate 100 with a first face 100a and a second face 100b opposite to each other. The first face 100a of the substrate 100 may be referred to as a front face of the substrate 100, and the second face 100b may be referred to as a rear face of the substrate 100. The second face 100b of the substrate 100 may be a light receiving face on which light is incident. That is, the image sensor 10_1 according to some example embodiments may be a backside-illuminated (BSI) type image sensor 10_1.

The pixel array PXA may further include a circuit layer CCL disposed on the first face 100a of the substrate 100. The color filter layer CFL and the lens array LSA may be sequentially disposed on the second face 100b of the substrate 100.

The substrate 100 may be a semiconductor substrate. For example, the substrate 100 may be made of bulk silicon or SOI (silicon-on-insulator). The substrate 100 may be a silicon substrate, or may be made of a material other than silicon, including, for example, silicon germanium, indium antimonide, a lead telluride compound, indium arsenide, indium phosphide, gallium arsenide or gallium antimonide. The substrate 100 may have a base substrate and an epitaxial layer formed on the base substrate.

The substrate 100 may include therein a plurality of areas having a different conductivity type from that of the substrate 100. For example, the substrate may include a first conductive material, and the areas may include a second conductive material. In some example embodiments, the first conductivity type may be a p-type, and the second conductivity type may be an n-type. For example, the areas may be formed by ion-implanting an n-type impurity, for example, phosphorus (P) or arsenic (As) into a p-type substrate 100 doped with boron (B).

The areas within the substrate 100 may include the first photoelectric conversion area LEC1 and the second photoelectric conversion area LEC2. For example, the first photoelectric conversion area LEC1 may be disposed in the first sub-pixel SPX1, and the second photoelectric conversion area LEC2 may be disposed in the second sub-pixel SPX2 isolated from the first sub-pixel SPX1 via the element isolation film PIL. The first photoelectric conversion area LEC1 may have a dimension in a horizontal direction greater than that of the second photoelectric conversion area LEC2. Further, a dimension in the third direction Z as a depth direction of the first photoelectric conversion area LEC1 may be smaller than that of the second photoelectric conversion area LEC2. However, the present disclosure is not limited thereto. The first and second photoelectric conversion areas LEC1 and LEC2 may be disposed between the first face 100a and the second face 100b of the substrate 100, and may be spaced from the first face 100a by a predefined (or, alternatively, desired, selected, etc.) distance. The spacing from the first face 100a of the substrate 100 to the first photoelectric conversion area LEC1 may be smaller than the spacing from the first face 100a of the substrate 100 to the second photoelectric conversion area LEC2. However, the present disclosure is not limited thereto.

The areas within the substrate 100 may further include the first floating diffusion area FD1 and the second floating diffusion area FD2. For example, the first floating diffusion area FD1 may be disposed in the first sub-pixel SPX1, and the second floating diffusion area FD2 may be disposed in the second sub-pixel SPX2. Each of the first floating diffusion area FD1 and the second floating diffusion area FD2 may be disposed adjacent to the first face 100a of the substrate 100. Each of the first and second floating diffusion areas FD1 and FD2 may have a higher impurity concentration than that of each of the first and second photoelectric conversion areas LEC1 and LEC2. However, the present disclosure is not limited thereto.

The element isolation film PIL may be further disposed inside the substrate 100. The element isolation film PIL may serve to isolate neighboring pixels PX from each other and neighboring sub-pixels SPX1 and SPX2 from each other. For example, the element isolation film PIL may play a role of blocking electric charge drift between the pixels PX, and between the sub-pixels SPX1 and SPX2.

In some example embodiments, the element isolation film PIL may extend from the first face 100a to the second face 100b of the substrate 100. One end in the extension direction of the element isolation film PIL may be disposed on the first face 100a of the substrate 100, and the other end in the extension direction of the element isolation film PIL may be disposed on the second face 100b of the substrate 100. In other words, the element isolation film PIL may extend through the substrate 100 in the third direction Z. However, the present disclosure is not limited thereto, and one end or the other end of the element isolation film PIL may be positioned inside the substrate 100 as in a trench shape.

The element isolation film PIL may be formed by removing a material constituting the substrate 100 and then filling a space obtained via the removal of the isolation film material. In some example embodiments, the element isolation film PIL may include a barrier layer PIL_B and a filling layer PIL_F. The barrier layer PIL_B may constitute a sidewall of element isolation film PIL. The barrier layer PIL_B may include a high dielectric constant insulating material. However, the present disclosure is not limited thereto. The barrier layer PIL_B may define a predefined (or, alternatively, desired, selected, etc.) space, and the filling layer PIL_F may be disposed in the space. The filling layer PIL_F may include, but is not limited to, a material having excellent gap-fill performance, for example, poly-silicon (poly-Si).

The circuit layer CCL disposed on the first face 100a of the substrate 100 may include various electrodes, wires, dielectrics, etc. to constitute the pixel PX circuit as shown in FIG. 6. The circuit layer PX may include, for example, gates TG1 and TG2, a gate insulating film 110, a gate spacer 120, interlayer insulating films 130 and 140, a contact electrode or a wiring layer WR, etc. As shown in FIG. 9, the gates TG1 and TG2 and/or the gate insulating film 110 may be partially buried into the substrate 100. However, the present disclosure is not limited thereto.

A passivation layer 150 may be disposed on the second face 100b of the substrate 100. The passivation layer 150 may include, for example, a high dielectric constant insulating material. Further, the passivation layer 150 may include an amorphous crystal structure.

In the drawing, a case in which the passivation layer 150 is composed of one layer is exemplified. However, the present disclosure is not limited thereto. In some example embodiments, the passivation layer 150 may further include a planarization layer and/or an anti-reflective layer. In this case, the planarization layer may include, for example, at least one of a silicon oxide-based material, a silicon nitride-based material, a resin, or a combination thereof. The anti-reflective layer may include a high dielectric constant material, for example, hafnium oxide (HfO₂). However, the technical spirit of the present disclosure is not limited thereto.

A grid pattern 160 may be disposed on the passivation layer 150. The grid pattern 160 may be disposed to overlap the element isolation film PIL. That is, the grid pattern 160 may be formed in a grid shape and may be disposed on the second face 100b of the substrate 100 and may be disposed to surround each of the pixels PX and each of the sub-pixels SPX1 and SPX2. The grid pattern 160 may play a role of reflecting the incident light incident at an angle to provide a larger amount of incident light to the photoelectric conversion areas LEC1 and LEC2.

The color filter layer CFL may be disposed on the passivation layer 150 on which the grid pattern 160 has been disposed. As described above, the color filter layer CFL includes the plurality of color filter patterns CFP, and the color filter patterns CFP of the same color may be disposed in one pixel PX. In the illustrated example, one integral color filter pattern CFP is disposed across the first sub-pixel SPX1 and the second sub-pixel SPX2. However, the color filter patterns CFP of the same color may be isolated from each other via the grid pattern 160 or the element isolation film PIL may be respectively disposed in the first sub-pixel SPX1 and the second sub-pixel SPX2.

The lens array LSA is disposed on the color filter layer CFL. The lens array LSA includes the plurality of micro lenses MLZ. One micro lens MLZ may protrude from a base face BSF. At least a partial area of each micro lens MLZ may have a convex face that is convex outwardly.

A planar shape of an outer boundary BDL; BDL1 and BDL2 of the micro lens MLZ may be a closed shape in a plan view (a planar shape may refer to an outline or two dimensional shape of a feature in a plan view). For example, the closed shape may be a curved closed curve such as a circle or an ellipse, a polygon such as an octagon, a hexagon, a rectangle, a square, or a rhombus, or a polygon with rounded corners.

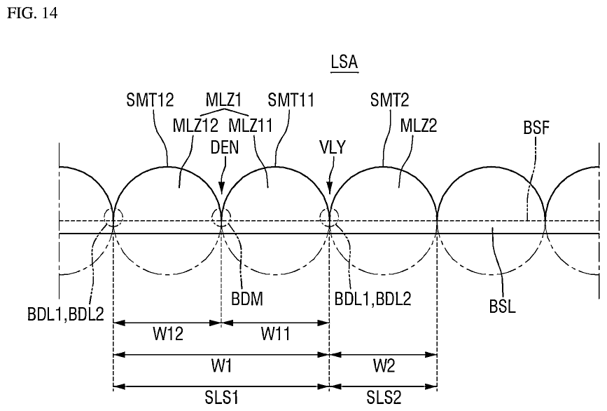

The outer boundary BDL of the micro lens MLZ may be disposed on the base face BSF. The outer boundary BDL of the micro lens MLZ has a smaller vertical dimension or a smaller thickness than that of the micro lens MLZ. This outer boundary BDL of the micro lens MLZ having the smaller vertical dimension may be referred to as a valley VLY (illustrated in FIG. 14).

In some example embodiments, the lens array LSA may include a base layer BSL disposed under the base face BSF of the plurality of micro lenses MLZ. A surface of the base layer BSL may constitute the base face BSF of the micro lens MLZ.

Separate base layers BSL may be respectively provided in a corresponding manner to separate micro lenses MLZ, separate pixels PX, and/or separate sub-pixels SPX1 and SPX2. However, the present disclosure is not limited thereto. The base layer BSL may be provided in an integral manner across the separate micro lenses MLZ, the separate pixels PX, and/or the separate sub-pixels SPX1 and SPX2. In the latter case, the plurality of micro lenses MLZ may be connected to each other via the base layer BSL.

In some example embodiments, the base layer BSL may be integrated with the micro lens MLZ. That is, the base layer BSL may be made of the same material as that of the micro lens MLZ, and the base layer BSL and the micro lens MLZ may constitute a single layer while a physical boundary is absent therebetween.

In some example embodiments, the base layer BSL may be a different layer than a layer of the micro lens MLZ. For example, a surface of the color filter layer CFL may serve as the base face BSF. A planarization film or another passivation film may be additionally interposed between the color filter layer CFL and the lens array LSA. In this case, a surface of the additionally interposed film may serve as the base face BSF.

Adjacent micro lenses MLZ may be connected to each other or may be spaced from each other. A criterion for distinguishing the connection and the spacing between neighboring micro lenses MLZ from each other may be based on whether a width of the valley VLY between the neighboring micro lenses MLZ is greater than or equal to 5% of an outer diameter of the micro lens MLZ.

The lens array LSA may include a first sub-lens area SLS1 corresponding to the first sub-pixel SPX1 and a second sub-lens area SLS2 corresponding to the second sub-pixel SPX2.

The first sub-lens area SLS1 may overlap the first sub-pixel SPX1 and may serve to condense incident light to the first photoelectric conversion area LEC1. The second sub-lens area SLS2 may overlap the second sub-pixel SPX2 and may serve to condense incident light to the second photoelectric conversion area LEC2. As described above, the first sub-pixel SPX1 may have a larger area than that of the second sub-pixel SPX2, such that an area covered with the first sub-lens area SLS1 may be also larger than that of an area covered with the second sub-lens area SLS2.

Each of the first sub-lens area SLS1 and the second sub-lens area SLS2 may include one or more micro lenses MLZ. A first micro lens MLZ1 included in the first sub-lens area SLS1 and a second micro lens MLZ2 included in the second sub-lens area SLS2 are identical with each other in that each at least partially includes a convex face, but differ from each other in terms of at least one of a shape, the number, and an arrangement thereof.

In some example embodiments as illustrated in FIG. 9, one first micro lens MLZ1 is disposed on the first sub-pixel SPX1, and one second micro lens MLZ2 is disposed on the second sub-pixel SPX2.

An outer boundary BDL2 of the second micro lens MLZ2 may lie on an edge of the second sub-pixel SPX2. The outer boundary BDL2 of the second micro lens MLZ2 may overlap the grid pattern 160. Further, the outer boundary BDL2 of the second micro lens MLZ2 may overlap the element isolation film PIL. In some example embodiments, a center (a central point in a width direction) of the valley VLY positioned around the second micro lens MLZ2 may be aligned with a center of the element isolation film PIL and a center of the grid pattern 160. A planar shape of the outer boundary BDL2 of the second micro lens MLZ2 may be substantially the same as that of the second sub-pixel SPX2. For example, the planar shape of the outer boundary BD2L of the second micro lens MLZ2 may be a square or a square with rounded corners.

The second micro lens MLZ2 may have a cross-sectional shape of a partial circle or a partial ellipse. A summit SMT2 of the second micro lens MLZ2 at which the second micro lens MLZ2 has the largest vertical dimension, that is, is the thickest, may be positioned at a center of the second micro lens MLZ2. The center of the second micro lens MLZ2 may be aligned with a center of the second sub-pixel SPX2. However, the present disclosure is not limited thereto. However, unless otherwise specified in the present disclosure, it is assumed that a center of the micro lens MLZ is aligned with a center of the underlying sub-pixel SPX. A cross-sectional shape of the second micro lens MLZ2 may have a symmetrical shape around the summit SMT2. Unlike the first micro lens MLZ1 as described later, the second micro lens MLZ2 may not include a depression at a central area.

An outer boundary BDL1 of the first micro lens MLZ1 may lie on an edge of the first sub-pixel SPX1. The outer boundary BDL1 of the first micro lens MLZ1 may overlap the grid pattern 160. Further, the outer boundary BDL1 of the first micro lens MLZ1 may overlap the element isolation film PIL. In some example embodiments, a center (a central point in a width direction) of the valley VLY positioned around the first micro lens MLZ1 may be aligned with the center of the element isolation film PIL and the center of the grid pattern 160. A planar shape of the outer boundary BDL1 of the first micro lens MLZ1 may be substantially the same as the planar shape of the first sub-pixel SPX1. For example, the planar shape of the outer boundary BDL1 of the first micro lens MLZ1 may be an octagon or an octagon with rounded corners.

The planar shape of the outer boundary BDL1 of the first micro lens MLZ1 may have a larger area size than that of the planar shape of the outer boundary BD2L of the second micro lens MLZ2.

In some example embodiments, a cross-sectional shape of the first micro lens MLZ1 differs from that of the second micro lens MLZ2. The first micro lens MLZ1 may be divided into a central area including the center thereof and a peripheral area positioned around the central area thereof. The central area may include a depression DEN. The peripheral area of the first micro lens MLZ1 may have a convexly protruding shape similar to that of the second micro lens MLZ2. However, in the central area of the first micro lens MLZ1, the first micro lens MLZ1 does not protrude and may be depressed toward the base face BSF. As shown in FIG. 9, the depression DEN may have a convex shape. However, the present disclosure is not limited thereto. The depression DEN may have a concave shape.

A summit SMT1 of the first micro lens MLZ1 may not be positioned at the center thereof, but may be positioned at an inflection point where the protruding shape is converted to the depressed shape. The center of the first micro lens MLZ1 may coincide with a center of the depression DEN. In a plan view, a line extending along the summit SMT1 of the first micro lens MLZ1 may have substantially the same planar shape as that of the outer boundary BDL1. For example, the planar shape of the line extending along each of summits SMT11 and SMT12 of the first micro lens MLZ1 and the planar shape of the outer boundary BDL1 of the first micro lens MLZ1 may be similar to each other, and may be respectively circles or polygons having the same center.

The first micro lens MLZ1 may be divided into a first portion MLZ11 as one side and a second portion MLZ12 as the other side around a center of the depression DEN. The center of the depression DEN positioned between the first portion MLZ11 and the second portion MLZ12 may be referred to as an inner boundary BDM.

In this way, the first micro lens MLZ1 has a protruding shape in an area between the outer boundary BDL1 and the center, and then is depressed at the inflection point. Thus, a maximum vertical dimension (that is, a vertical dimension of the summit SMT1) of the first micro lens MLZ1 may be decreased compared to a maximum vertical dimension thereof in a case in which a vertical dimension of the first micro lens MLZ1 continuously increases from the outer boundary BDL1 toward the center. Therefore, an amount by which the first micro lens MLZ1 blocks incident light into the second micro lens MLZ2 adjacent thereto may be lowered.

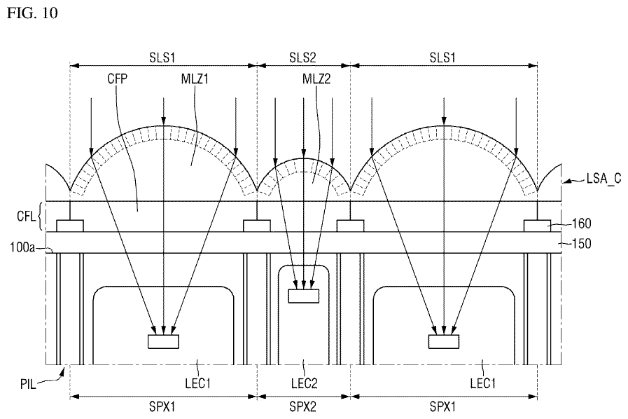

With reference to FIG. 10 to FIG. 13, an effect of a structure of the first micro lens MLZ1 on the incident light to the second micro lens MLZ2 adjacent thereto is described in more detail.

FIG. 10 to FIG. 13 are respective schematic diagrams showing light paths through lens arrays according to some example embodiments. For convenience of illustration, each of FIG. 10 to FIG. 13 is a turned upside-down drawing of that as shown in FIG. 9.

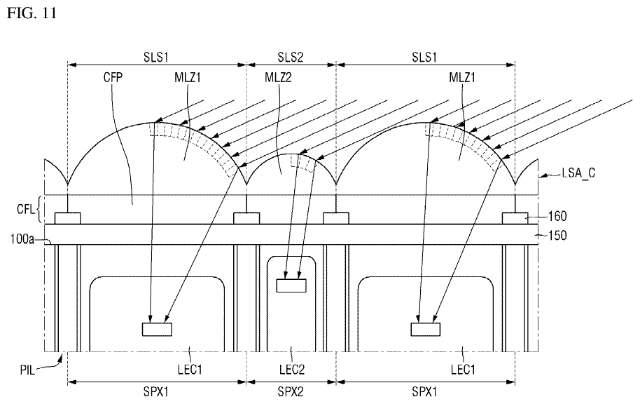

FIG. 10 and FIG. 11 show propagation paths of light incident in a normal direction and light incident in an oblique direction in some example embodiments in which the first micro lens MLZ1 has a shape similar to that of the second micro lens MLZ2 but has a summit having a higher vertical level than that of the second micro lens MLZ2.

Incident light incident to the lens array LSA_C may be refracted based on an angle of incidence determined based on a surface shape of each of the first micro lens MLZ1 and the second micro lens MLZ2, and a change in a refractive index at a boundary of a medium, and may travel into the substrate 100.

When light is incident in the normal direction to the lens array LSA_C, the light (that is, normal light) may be condensed to a position corresponding to a designed focal distance of each of first and second micro lenses MLZ1 and MLZ2, as shown in FIG. 10.

When light is incident at an angle to the lens array LSA_C, light (that is, oblique light) is refracted at a surface of each of the first and second micro lenses MLZ1 and MLZ2 and propagates toward the substrate 100, as shown in FIG. 11.

The normal light may reach an entirety of a surface of each of the first micro lens MLZ1 and the second micro lens MLZ2 when there is no obstacle in the optical path. However, the oblique light may not reach the entirety of the surface thereof because the light is partially blocked with the adjacent micro lens MLZ. In particular, an amount of the oblique light reaching the surface of the second micro lens MLZ2 which is relatively smaller in size may be reduced because the oblique light is partially blocked with the first micro lens MLZ1 adjacent thereto. Accordingly, an amount of the oblique light entering the second sub-pixel SPX2 may be reduced, such that light sensing accuracy of the second sub-pixel SPX2 may be lowered.

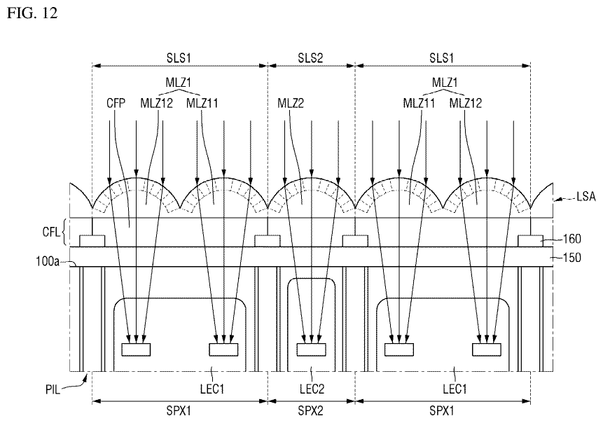

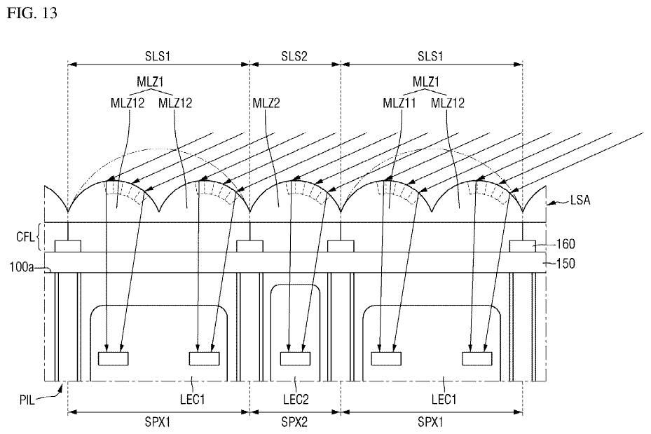

FIG. 12 and FIG. 13 are respective schematic diagrams showing propagation paths of light incident in the normal direction and light incident in the oblique direction in a case where the first micro lens MLZ1 of the lens array LSA has the shape as shown in some example embodiments of FIG. 9.

In some example embodiments of FIG. 13, the summit SMT1 of the first micro lens MLZ1 adjacent to the second micro lens MLZ2 has a smaller vertical dimension than that of some example embodiments of FIG. 11. Therefore, the oblique light blocking effect by the first micro lens MLZ1 may be reduced by a reduced vertical dimension, such that the oblique light may reach a larger area of the surface of the second micro lens MLZ2, thereby increasing the light sensing accuracy of the second sub-pixel SPX2.

In the example shown in FIG. 13, a cross section of the first micro lens MLZ1 is similar to that of a combination of two adjacent micro lenses MLZ2. Therefore, the oblique light may reach both a first portion MLZ11 positioned at one side (at aright side of the drawing) from a center of the first micro lens MLZ1 around an extension direction of a straight line connecting a center of the first micro lens MLZ1 and a center of the second micro lens MLZ2 adjacent thereto, and a second portion MLZ12 positioned at the other side (at a left side in the drawing) from the center of the first micro lens MLZ1 around the extension direction. Although light directed toward the second portion MLZ12 is partially blocked with the first portion MLZ11, the light has already reached the surface of the first portion MLZ11 and has already entered an inside of the first sub-pixel SPX1. Thus, theoretically, no light loss occurs.

As shown in FIG. 12, an entirety of the normal light may be condensed through the first portion MLZ11 and the second portion MLZ12 of the first micro lens MLZ1.

In FIG. 12 and FIG. 13, a cross-sectional shape of the first micro lens MLZ1 is substantially similar to that of the combination of the adjacent two second micro lenses MLZ2, so that a position at which the incoming light is condensed may vary depending on an area which the incoming light reaches. In addition, the light incident at the same angle may be condensed at two or more areas. When various optical paths and various areas at which the light is condensed occur due to the shape of the first micro lens MLZ1, the photoelectric conversion may be performed in a wider area of the first photoelectric conversion area LEC1. Therefore, higher efficiency of the first photoelectric conversion area LEC1 and durability thereof against deterioration may be expected.

Hereinafter, various arrangements of micro lenses MLZ of the lens array LSA are described.

FIG. 14 is a cross-sectional view of a lens array according to some example embodiments.

As shown in FIG. 14, the lens array LSA may include the base layer BSL of a predefined (or, alternatively, desired, selected, etc.) thickness. One face of the base layer BSL may be referred to as the base face BSF, and the other face of the base layer BSL may be referred to as a back or rear face. The base face BSF may be a face on which the valley VLY of the micro lens MLZ disposed thereon planarly extends. The base face BSF may be flat. The back face of the base layer BSL may also be flat and may be parallel to the base face BSF.

In some example embodiments, a width W1 (a dimension in a horizontal direction) of the first micro lens MLZ1 may be twice a width W2 of the second micro lens MLZ2. In this regard, “A is twice B” includes not only a case in which A is numerically exactly twice B but also a case in which A is approximately twice B such that an error within ±10% of two times of A occurs. This interpretation will be applied equally to other multiples as described below. When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values, shapes, and relative dimensions/relationships should be construed as including a manufacturing or operational tolerance (e.g., ±10%) around the stated numerical values or shapes.

A cross section of the first portion MLZ11 (hereinafter, the first portion MLZ11) of the first micro lens MLZ1 as one side around the depression DEN, and a cross section of the second portion MLZ12 (hereinafter, the second portion MLZ12) of the first micro lens MLZ1 as the opposite side thereto around the depression DEN may be symmetrical with each other around the depression DEN. In some example embodiments, a shape of the cross section of each of the first portion MLZ11, the second portion MLZ12, and the second micro lens MLZ2 may be a partial circle, for example, a semi-circle. A center of the semi-circle of each of the first portion MLZ11, the second portion MLZ12, and the second micro lens MLZ2 may be positioned at the base face BSF. In addition, not only the valley VLY between the first micro lens MLZ1 and the second micro lens MLZ2, but also the inner boundary BDM between the first portion MLZ11 and the second portion MLZ12 may be positioned at the base face BSF.

A width W11 in a horizontal direction of the first portion MLZ11, a width W12 in a horizontal direction of the second portion MLZ12, and a width W2 in a horizontal direction of the second micro lens MLZ2 may be equal to each other. Further, a radius of the semi-circle of the first portion MLZ11, a radius of the semi-circle of the second portion MLZ12, and a radius of the semi-circle of the second micro lens MLZ2 may be equal to each other. In other words, a curvature radius of the first portion MLZ11, a curvature radius of the second portion MLZ12, and a curvature radius of the second micro lens MLZ2 may be equal to each other. FIGS. 14-18 illustrate continued (dashed) circles representing curvature radius of the various features the circles are attached to for clarity of the curvature radius (for example of the first portion MLZ11, second portion MLZ12, and second micro lens MLZ2 in FIG. 14).

The summit SMT1; SMT11 and SMT12 as the highest protruding portion of the first micro lens MLZ1 may be positioned at each of a center of the first portion MLZ11 and a center of the second portion MLZ12. A line extending along the summit SMT1 of the first micro lens MLZ1 may be a closed curve such as a circle in a plan view.

The summit SMT2 of the second micro lens MLZ2 may be positioned at the center of the second micro lens MLZ2. Each of a vertical dimension (a dimension measured in the thickness direction) from the valley VLY of the micro lens MLZ, that is, the base face BSF to the summit SMT1 of the first micro lens MLZ1, and a vertical dimension from the valley VLY of the micro lens MLZ, that is, the base face BSF to the summit SMT2 of the second micro lens MLZ2 may be equal to a radius of the semi-circle. In this regard, “A being equal to B” includes not only a case where A and B are numerically exactly equal to each other, but also a case where A and B are approximately equal to each other such that an error within ±10% thereof occurs. This interpretation may be equally applied to the numerical dimension as described below.

In this way, in some example embodiments of FIG. 14, the first portion MLZ11, the second portion MLZ12, and the second micro lens MLZ2 having substantially the same cross-sectional shape are consecutively arranged, such that the light blocking effect due to the difference between the vertical dimensions of the micro lenses may be prevented or reduced.

In one example, in FIG. 14, it is assumed that each of the first portion MLZ11, the second portion MLZ12, and the second micro lens MLZ2 has a uniform curvature (or a uniform radius of curvature) in an entire area in the width direction. However, the technical idea of the present disclosure is not limited thereto. For example, the curvature of the second micro lens MLZ2 may have different values based on different positions thereof in the width direction, or may continuously vary based on a varying position in the width direction. In this case, this modification may be equally applied to each of the first portion MLZ11 and the second portion MLZ12 of the first micro lens MLZ1.

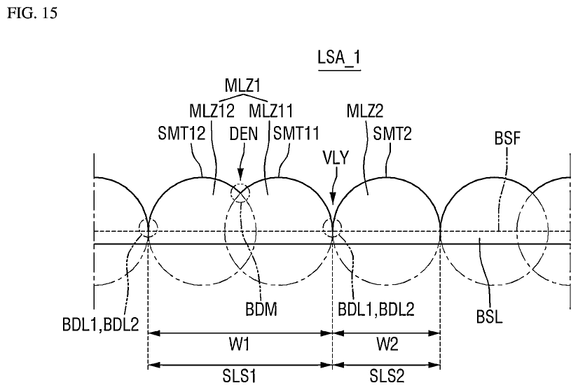

FIG. 15 is a cross-sectional view of a lens array according to some example embodiments.

In some example embodiments, the width W1 (the dimension in the horizontal direction) of the first micro lens MLZ1 of the lens array LSA_1 may be smaller than twice of the width W2 of the second micro lens MLZ2. FIG. 15 shows a modification example of the micro lens MLZ in FIG. 14 modified under this condition.

The first portion MLZ11, the second portion MLZ12, and the second micro lens MLZ2 may respectively be portions of circles having the same radius. Centers of the circles may be positioned at the base face BSF. In the cross-sectional view, the second micro lens MLZ2 may have a semicircular shape, while a semicircle of the first portion MLZ11 and a semicircle of the second portion MLZ12 may partially overlap each other.

The valley VLY between the first micro lens MLZ1 and the second micro lens MLZ2 may be positioned at the base face BSF, while the inner boundary BDM between the first portion MLZ11 and the second portion MLZ12 may be positioned at a higher level than that of the base face BSF.

The summit SMT as the highest protruding portion of the first micro lens MLZ1 may be positioned at each of the first portion MLZ11 and the second portion MLZ12. The summit SMT11 of the first portion MLZ11 may be positionally deviated from the center of the first portion MLZ11 toward the second portion MLZ12, while the summit SMT12 of the second portion MLZ12 may be positionally deviated from the center of the second portion MLZ12 toward the first portion MLZ11. The summit SMT2 of the second micro lens MLZ2 may be positioned at the center of the second micro lens MLZ2.

The vertical dimension from the base face BSF to the summit SMT1 of the first micro lens MLZ1 and the vertical dimension from the base face BSF to the summit SMT2 of the second micro lens MLZ2 may be equal to each other.

In some example embodiments of FIG. 15, the first portion MLZ11 and the second portion MLZ12 of the first micro lens MLZ1 may partially overlap each other, while the first portion MLZ11, the second portion MLZ12, and the second micro lens MLZ2 respectively having the summits SMT11, SMT12, and SMT2 of the same vertical dimension may be consecutively arranged. Thus, the light blocking effect caused by the difference between the vertical dimensions of the micro lenses may be prevented or reduced. In addition, although a size of a curved section of the inner boundary BDM is reduced due to the overlapping between the semi-circles of the first portion MLZ11 and the second portion MLZ12, a size of a curved section of the outer boundary BDL1 which has a greater effect on the light condensing efficiency is substantially equal to that in some example embodiments of FIG. 14. Thus, the light condensing efficiency may not be significantly affected.

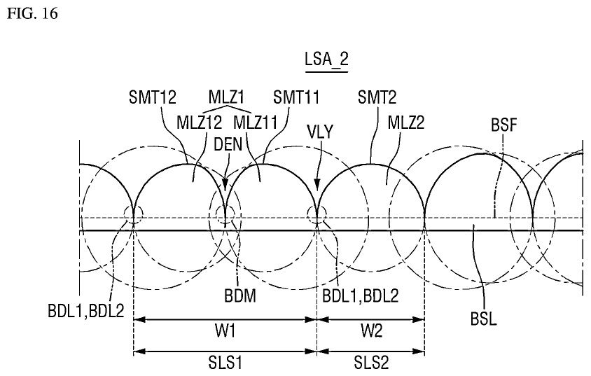

FIG. 16 is a cross-sectional view of a lens array according to some example embodiments.

A lens array LSA_2 in FIG. 16 illustrates some example embodiments of an arrangement of the micro lenses MLZ when the width W1 (the dimension in the horizontal direction) of the first micro lens MLZ1 is smaller than twice the width W2 of the second micro lens MLZ2, as in FIG. 15. FIG. 16 illustrates that the first micro lens MLZ1 may have different curvatures (or radius of curvatures) at specific different locations.

Referring to FIG. 16, each of the summit SMT11 of the first portion MLZ11 and the summit SMT12 of the second portion MLZ12 is positionally deviated from the center thereof toward the inner boundary BDM, as shown in FIG. 15. An area (hereinafter, referred to as “summit outer area PEL”) between the outer boundary BDL1 and each of the summits SMT11 and SMT12 in each of the first portion MLZ11 and the second portion MLZ12 has the same curvature radius as that of the second micro lens MLZ2. However, an area (hereinafter, referred to as “summit inner area PEM”) between the inner boundary BDM and each of the summits SMT11 and SMT12 in each of the first portion MLZ11 and the second portion MLZ12 has a radius of curvature larger than that of the second micro lens MLZ2. The inner boundary BDM between the first portion MLZ11 and the second portion MLZ12 may be positioned at a higher level than that of the base face BSF, but may be positioned at a lower level than that in the example of FIG. 15.

In a modification example of FIG. 16, the curvature may vary depending on a varying position in each of the summit outer area PEL and the summit inner area PEM of the first micro lens MLZ1. Even in this case, the radius of curvature of the summit inner area PEM may be smaller than that of the radius of curvature of the summit outer area PEL.

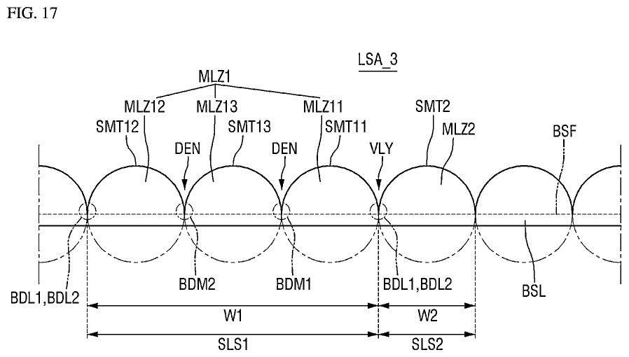

FIG. 17 is a cross-sectional view of a lens array according to some example embodiments.

FIG. 17 illustrates that the first micro lens MLZ1 of a lens array LSA_3 may include three portions arranged in the width direction. For example, the width W1 (the dimension in the horizontal direction) of the first micro lens MLZ1 may be three times the width W2 of the second micro lens MLZ2. The first micro lens MLZ1 may further include a third portion MLZ13 positioned between the first portion MLZ11 and the second portion MLZ12 in addition to the first portion MLZ11 and the second portion MLZ12. A first inner boundary BDM1 may be positioned between the first portion MLZ11 and the third portion MLZ13, and a second inner boundary BDM2 may be positioned between the third portion MLZ13 and the second portion MLZ12. In the plan view, each of the first inner boundary BDM1 and the second inner boundary BDM2 may extend along a closed curve. The closed curve defined by each of the first inner boundary BDM1 and the second inner boundary BDM2 may be circular or the same as the planar shape of the outer boundary BDL1 of the first micro lens MLZ1. For example, the closed curves respectively defined by the first inner boundary BDM1 and the second inner boundary BDM2 may be similar to each other and may respectively be circles or polygons having the same center.

In the third portion MLZ13, a summit SMT13 may be positioned at the center of the first micro lens MLZ1. The first portion MLZ11, the second portion MLZ12, and the third portion MLZ13 may have the same cross-sectional shape. The second micro lens MLZ2 may also have the same cross-sectional shape as that of each of the first portion MLZ11, the second portion MLZ12, and the third portion MLZ13.

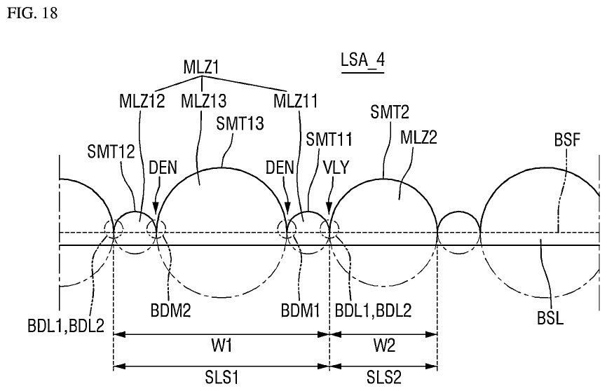

FIG. 18 is a cross-sectional view of a lens array according to some example embodiments.

FIG. 18 illustrates that the first portion MLZ11, the second portion MLZ12, and the third portion MLZ13 of the lens array LSA_4 may have different sizes. For example, the third portion MLZ13 positioned in the central area of the first micro lens MLZ1 may have a larger size than that of each of the first portion MLZ11 and the second portion MLZ12 positioned in the peripheral area thereof. Therefore, the summit SMT13 of the third portion MLZ13 may be positioned at a higher level than that of each of the summits SMT11 and SMT12 of the first portion MLZ11 and the second portion MLZ12. A size of each of the first portion MLZ11 and the second portion MLZ12 may be smaller than or equal to the size of the second micro lens MLZ2. Thus, when a large sized micro lens is required in a specific area, the large sized micro lens may be placed in an area relatively far from the second micro lens MLZ2, thereby minimizing the blocking effect of the incident light to the second micro lens MLZ2.

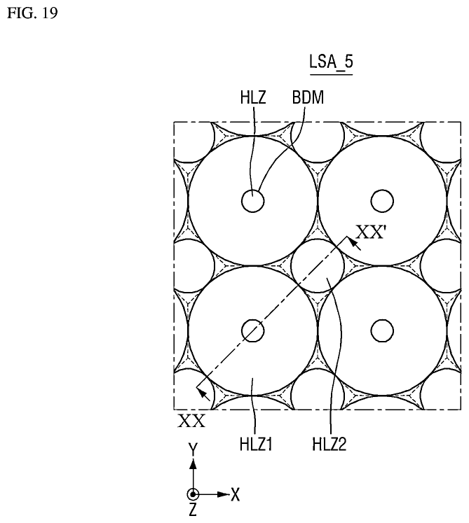

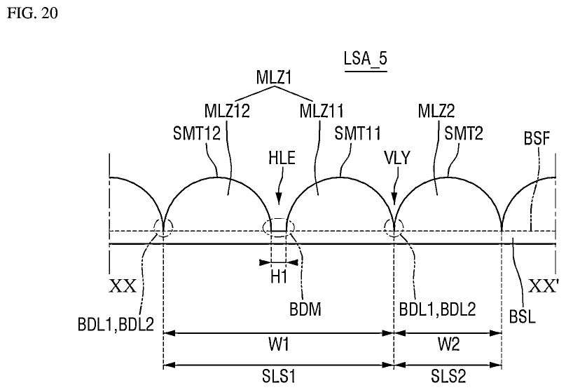

FIG. 19 is a plan layout diagram of an image sensor according to some example embodiments. FIG. 20 is a cross-sectional view taken along a line XX-XX′ in FIG. 19.

FIG. 19 and FIG. 20 illustrate that the depression positioned in the central area of the first micro lens MLZ1 of a lens array LSA_5 may include a hole HLE.

The central area of the first micro lens MLZ1 may be depressed to form the hole HLE. The inner boundary BDM of the first micro lens MLZ1 may extend in a closed curve in a plan view. The closed curve defined by the inner boundary BDM may be circular or the same as the planar shape of the outer boundary BDL. For example, the closed curve defined by the inner boundary BDM and the planar shape of the outer boundary BDL may be similar to each other and may respectively be circles or polygons having the same center. The planar shape of the first micro lens MLZ1 defined by the inner boundary BDM and the outer boundary BDL may be a donut shape.

The hole HLE of the central area may expose a portion of the base face BSF. In the cross-sectional view, the first micro lens MLZ1 may be divided into the first portion MLZ11 and the second portion MLZ12 via the hole HLE. The first portion MLZ11 and the second portion MLZ12 may be spaced apart from each other by a width or a diameter H1 of the hole HLE. A center of the central area hole HLE may coincide with the center of the first micro lens MLZ1. In the drawing, a case in which the cross-sectional shapes and the sizes of the first portion MLZ11 and the second portion MLZ12 and the cross-sectional shape and the size of the second micro lens MLZ2 are identical with each other is illustrated. However, the cross-sectional shapes and the sizes thereof may be variously modified without departing from the scope of the technical idea of the present disclosure.

In this way, the lens array LSA_5 may have the hole HLE in the central area to further reduce the vertical dimension of each of the summits SMT11 and SMT12 of the first micro lens MLZ1. Therefore, the blocking effect of the incident light to the adjacent second micro lens MLZ2 may be reduced. Some example embodiments as illustrated in FIG. 19 and FIG. 20 may be usefully selected when the width W1 of the first micro lens MLZ1 is greater than or equal to the two times of the width W2 of the second micro lens MLZ2.

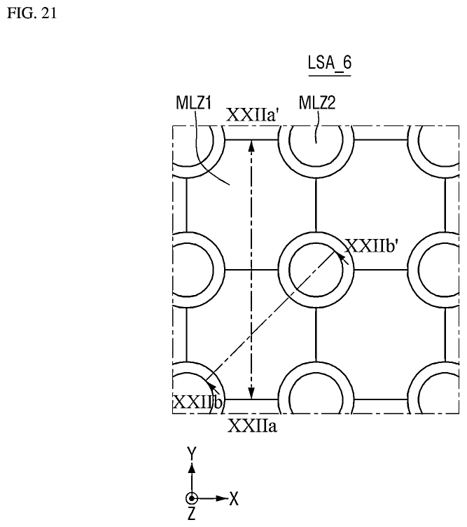

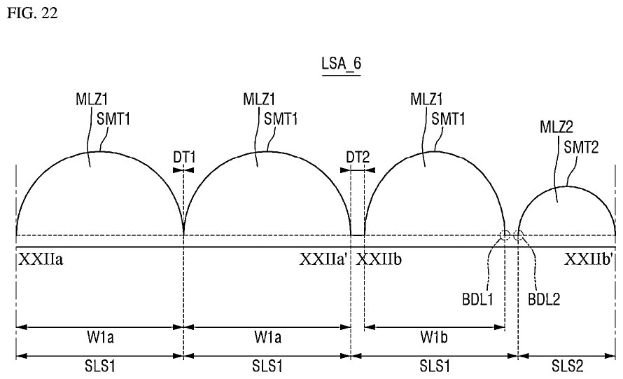

FIG. 21 is a plan layout diagram of an image sensor according to some example embodiments. FIG. 22 is a cross-sectional view taken along each of lines XXIIa-XXIIa′ and XXIIb-XXIIb′ of FIG. 21.

FIG. 21 and FIG. 22 show an example in which the first micro lens MLZ1 of a lens array LSA_6 does not include the depression DEN in an inner area thereof, but the outer boundary BDL1 thereof adjacent to the second micro lens MLZ2 is displaced inwardly so that the outer boundary BDL1 is spaced apart from the second micro lens MLZ2.

The summit SMT1 of the first micro lens MLZ1 may be positioned at the center thereof. A vertical dimension of summit SMT1 of the first micro lens MLZ1 may be greater than a vertical dimension of the summit SMT2 of the second micro lens MLZ2.

In some example embodiments, a width W1b in a diagonal direction of the first micro lens MLZ1 may be smaller than a width W1a in each of the first direction X and the second direction Y of the first micro lens MLZ1. The first micro lenses MLZ1 adjacent to each other in each of the first direction X and the second direction Y may be connected to each other (that is, a spacing therebetween may be 0) or may be spaced from each other by a first distance DT1. The first micro lens MLZ1 and the second micro lens MLZ2 adjacent to each other in the diagonal direction may be spaced apart from each other by a second distance DT2 greater than the first distance DT1.

The first micro lens MLZ1 may have different curvatures along a cross-section direction. For example, the first micro lens MLZ1 may have a first radius of curvature in a cross-section cut along each of the first direction X and the second direction Y, and a second radius of curvature in a cross section cut along the diagonal direction, wherein the second radius of curvature may be greater than the first radius of curvature.

Referring to FIG. 22, a position of the first micro lens MLZ1 adjacent to the second micro lens MLZ2 in the diagonal direction is displaced inwardly while a position of the first micro lens MLZ1 in each of the first and second directions X and Y is not displaced inwardly. Further, a spacing between the first micro lens MLZ1 and the second micro lens MLZ2 is larger than a spacing between two portions of the first micro lens MLZ1 spaced apart from each other in each of the first and second directions X and Y (that is, DT2>DT1). Therefore, a larger space may be secured between the first micro lens MLZ1 and the second micro lens MLZ2, such that the blocking effect of the incident light to the second micro lens MLZ2 may be reduced by a distance by which a position of the first micro lens MLZ1 adjacent to the second micro lens MLZ2 in the diagonal direction is displaced inwardly.

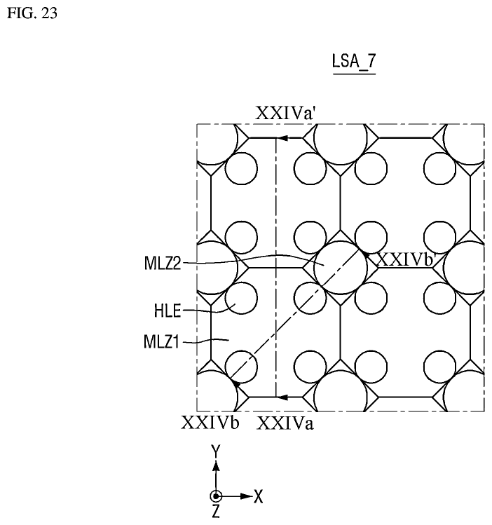

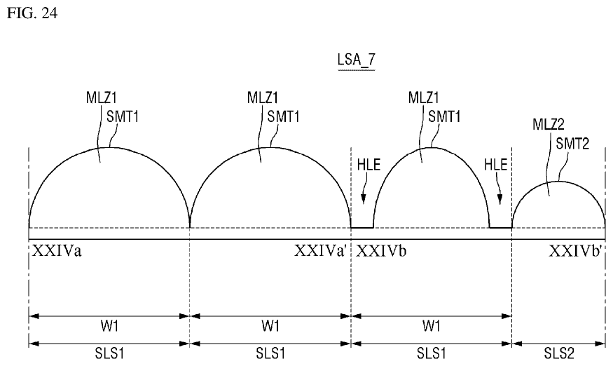

FIG. 23 is a plan layout diagram of an image sensor according to some example embodiments. FIG. 24 is a cross-sectional view taken along each of lines XXIVa-XXIVa′ and XXIVb-XXIVb′ in FIG. 23.

Referring to FIG. 23 and FIG. 24, the first micro lens MLZ1 of a lens array LSA_7 may include a hole HLE near the outer boundary BDL adjacent to the second micro lens MLZ2. The hole HLE may also overlap the outer boundary BDL1 of the first micro lens MLZ1 or constitute a portion of the outer boundary BDL1. The planar shape of the hole HLE may be circular. However, the present disclosure is not limited thereto. The center of the hole HLE may be positioned outside the center of the first micro lens MLZ1. Furthermore, an entirety of the hole HLE may be positioned outside the center of the first micro lens MLZ1. The summit SMT1 may be positioned at the center of the first micro lens MLZ1.

As the first micro lens MLZ1 includes the hole HLE, a larger spacing may be secured between the first micro lens MLZ1 and the second micro lens MLZ2. The blocking effect of the incident light to the adjacent second micro lens MLZ2 may be reduced by the space secured by the hole HLE of the first micro lens MLZ1.

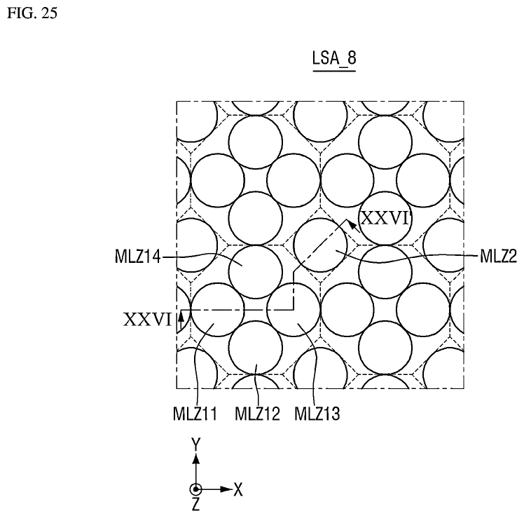

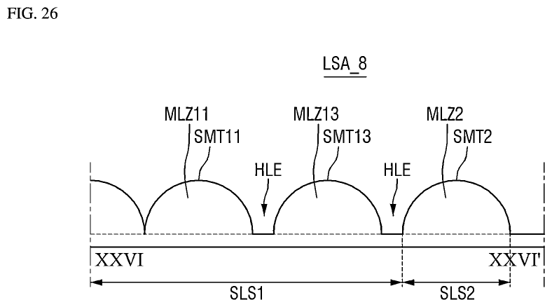

FIG. 25 is a plan layout diagram of an image sensor according to some example embodiments. FIG. 26 is a cross-sectional view taken along each of lines XXVI-XXVI′ in FIG. 25.

FIG. 25 and FIG. 26 illustrate that the first sub-lens area SLS1 of a lens array LSA_8 may include a plurality of micro lenses. For example, the first sub-lens area SLS1 may include four micro lenses MLZ11 to MLZ14 as shown in FIG. 25. For convenience of illustration, the four micro lenses are referred to as the first to fourth sub-micro lenses MLZ11 to MLZ14, respectively. The number of the second micro lenses MLZ2 in the second sub-lens area SLS2 may be smaller than the number of the micro lenses in the first sub-lens area SLS1. A case where one second micro lens MLZ2 is disposed in the second sub-lens area SLS2 is illustrated in the drawings.

The first to fourth sub-micro lenses MLZ11 to MLZ14 may have the same shape and the same size. Further, each of the first to fourth sub-micro lenses MLZ11 to MLZ14 may also have the same shape and the same size as those of the second micro lens MLZ2. However, the present disclosure is not limited thereto.

The first sub-micro lens MLZ11 and the third sub-micro lens MLZ13 may be arranged along the first direction X, and the second sub-micro lens MLZ12 and the fourth sub-micro lens MLZ14 may be arranged along the second direction Y. The first sub-micro lens MLZ11 and the second sub-micro lens MLZ12 may be adjacent to each other, while the second sub-micro lens MLZ12 and the third sub-micro lens MLZ13 may be adjacent to each other, while the third sub-micro lens MLZ13 and the fourth sub-micro lens MLZ14 may be adjacent to each other, while the fourth sub-micro lens MLZ14 and the first sub-micro lens MLZ11 may be adjacent to each other.

A space surrounded with the first to fourth sub-micro lenses MLZ11 to MLZ14 may be a space exposing a portion of the base face BSF as the hole exposes a portion of the base face BSF. A center of the first sub-lens area SLS1 may be not covered with the first to fourth sub-micro lenses MLZ11 to MLZ14 such that the base face BSF may be exposed through the exposed center.

Further, a space exposing a portion of the base face BSF may also be defined between each of the first to fourth sub-micro lenses MLZ11 to MLZ14 and the second micro lens MLZ2 adjacent thereto.

In this way, the first sub-pixel SPX1 may be covered with the plurality of sub-micro lenses MLZ11 to MLZ14. In this case, a vertical dimension of each of the summit SMT11 and SMT13 may be decreased compared to that in a case where the first sub-pixel SPX1 is covered with one first micro lens having a larger radius of curvature than that of each of the plurality of sub-micro lenses MLZ11 to MLZ14. In addition, the space may be provided between each of the micro lenses MLZ11 to MLZ14 and the second micro lens MLZ2, such that the blocking effect of the incident light to the second micro lens MLZ2 may be reduced.

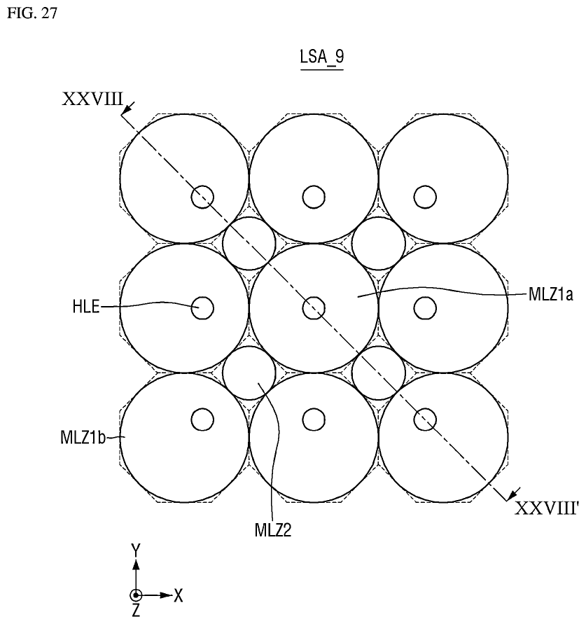

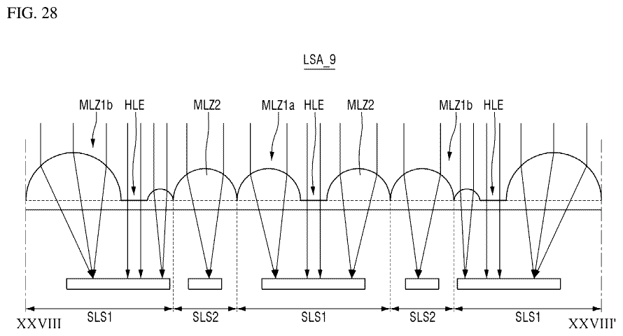

FIG. 27 is a plan layout diagram of an image sensor according to some example embodiments. FIG. 28 is a cross-sectional view taken along each of lines XXVIII-XXVIII′ of FIG. 27.

FIG. 27 and FIG. 28 illustrate that in a lens array LSA_9, the first micro lenses MLZ1 of different shapes may be applied to different first sub-pixels SPX1.

For example, one first micro lens MLZ1 may be disposed in each of the plurality of first sub-pixels SPX1, wherein each of some first micro lenses MLZ1a thereof may have a hole HLE at a center thereof, while each of the other first micro lenses MLZ1b thereof may include a hole HLE positionally deviated from a center thereof. As shown in the drawings, a 3×3 array as a portion of an array of the first micro lenses MLZ1 is taken by way of example. The first micro lens MLZ1a of the first sub-pixel SPX1 positioned at a center of the 3×3 array may have the hole HLE at a center thereof, while each of eight first micro lenses MLZ1b of the first sub-pixel SPX1 positioned around the first micro lens MLZ1a may have the hole HLE positionally deviated from a center thereof toward the first micro lens MLZ1a. The hole HLE may overlap or non-overlap with the center of the first micro lens MLZ1a or MLZ1b.

For example, the hole HLE positionally deviated from the center may overlap the outer boundary BDL1 as shown in FIG. 23, or may be positioned inwardly of the outer boundary BDL1 as shown in FIG. 27 and FIG. 28. In this case, an area of the first micro lens MLZ1 having a curvature may also be disposed between the hole HLE and the outer boundary BDL adjacent thereto. As shown in FIG. 28, a radius of curvature in an area from the hole HLE to an outer boundary BDL closer to the hole may be smaller than a radius of curvature in an area from the hole HLE to an outer boundary BDL far away from the hole.

In the example shown in FIG. 27 and FIG. 28, the first micro lens MLZ1 includes the hole HLE such that the vertical dimension of the summit may be decreased or the space may be secured by the hole HLE. Therefore, the blocking effect of the incident light to the second micro lens may be reduced.

In addition, the above-described arrangement of the first micro lenses MLZ1a and MLZ1b has an effect of condensing the incident light toward the first sub-pixel SPX1 positioned in a central area, as shown in FIG. 28. In other words, when the above-described arrangement of the first micro lenses MLZ1a and MLZ1b is applied, a position to which the light is condensed may be tuned in various ways without additional measures such as moving a global lens. In addition, when a pixel PX of a specific color among pixels PX of different colors requires reception of a large amount of the light, the above-described arrangement of the first micro lenses MLZ1a and MLZ1b may be applied. For example, when the blue pixel PX requires reception of a large amount of the light, the blue pixel PX may be disposed in the central area, and the red and green pixels PX may be disposed around the blue pixel.

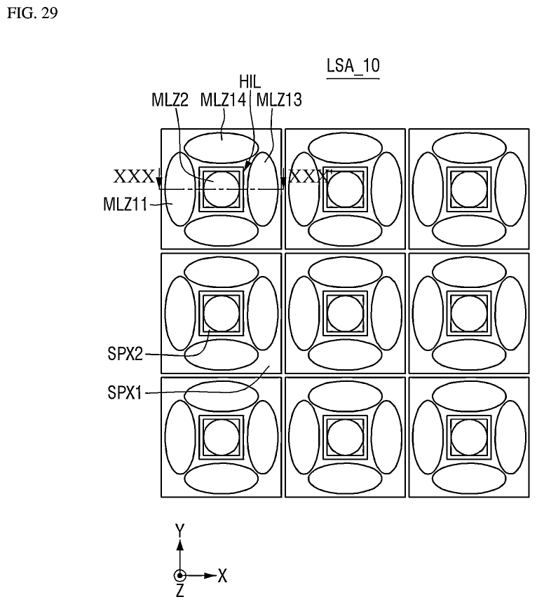

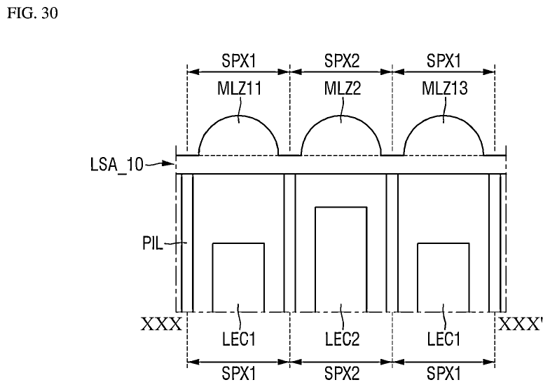

FIG. 29 is a plan layout diagram of an image sensor according to some example embodiments. FIG. 30 is a cross-sectional view taken along an XXX-XXX′ line in FIG. 29.

FIG. 29 and FIG. 30 illustrate a case where the second sub-pixel SPX2 is surrounded with the first sub-pixel SPX1. The pixel PX may have a square shape and the pixels may be arranged along each of the first direction X and the second direction Y. Each pixel PX may include the first sub-pixel SPX1 surrounding a closed hole HIL and the second sub-pixel SPX2 disposed inside the closed hole HLL.

A lens array LSA_10 includes the first sub-lens area SLS1 covering the first sub-pixel SPX1 and the second sub-lens area SLS2 covering the second sub-pixel SPX2. The second sub-lens area SLS2 positioned in the central area may include one second micro lens MLZ2. The first sub-lens area SLS1 may include one or more first micro lens MLZ1 surrounding the second micro lens MLZ2. For example, the first micro lens MLZ1 surrounding the hole HIL may be disposed to surround the second micro lens MLZ2. As shown in the drawing, four sub-micro lenses MLZ11 to MLZ14 may be disposed along four sides of the square-shaped pixel PX, respectively. When the first sub-lens area SLS1 includes the four sub-micro lenses MLZ11 to MLZ14, a planar shape of each of the sub-micro lenses MLZ11 to MLZ14 may be an ellipse. However, the present disclosure is not limited thereto.

In FIG. 29 and FIG. 30, the first sub-pixel SPX1 surrounds the hole HIL at the central area of the pixel. Thus, one first micro lens MLZ1 or the plurality of sub-micro lenses MLZ11 to MLZ14 may have a smaller width, such that the vertical dimension of the summit SMT may be similar to the vertical dimension of the summit SMT of the second micro lens MLZ2. Therefore, the blocking effect of the incident light to the second micro lens MLZ2 may be reduced.

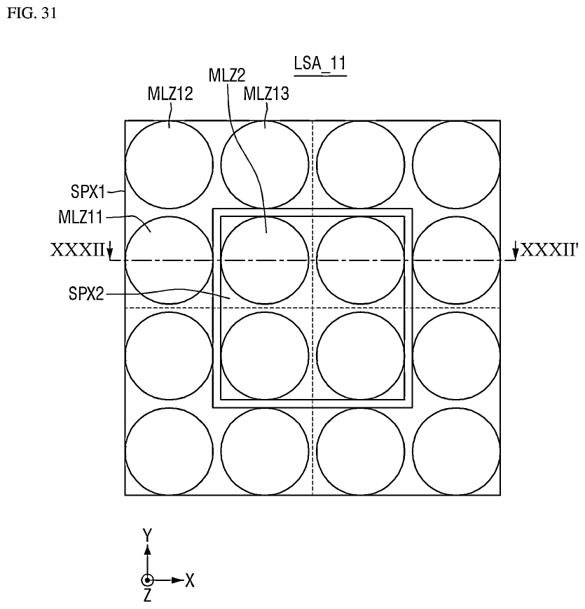

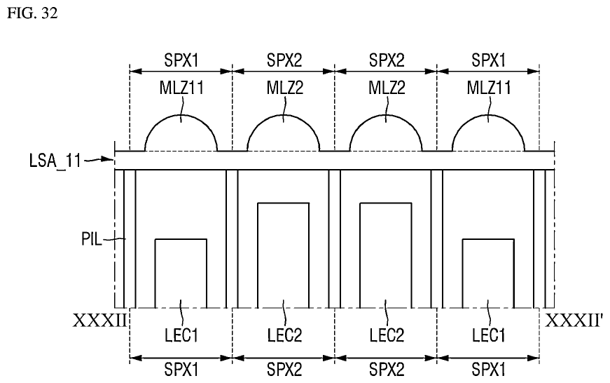

FIG. 31 is a plan layout diagram of an image sensor according to some example embodiments. FIG. 32 is a cross-sectional view taken along an XXXII-XXXII′ line in FIG. 31.

FIG. 31 and FIG. 32 illustrate a pixel PX structure in which a plurality of second sub-pixels SPX2 are adjacent to each other and are surrounded with a plurality of first sub-pixels SPX1.

An area of the first sub-pixel SPX1 may be three times of an area of the second sub-pixel SPX2. For example, the pixel PX may be divided into four equal areas along the first direction X and the second direction Y. Three areas of the four equal areas may be used as the first sub-pixel SPX1, while one area of the four equal areas may be used as the second sub-pixel SPX2. Each of adjacent pixels PX to the above pixel PX may have the same arrangement of the first and second sub-pixels SPX1 and SPX2. The second sub-pixels SPX2 of the adjacent pixels PX may be adjacent to each other. In this arrangement, the pixels PX may be grouped based on an area such that the pixels perform light sensing in the grouped manner.

In a lens array LSA_11, the second sub-lens area SLS2 covering the second sub-pixel SPX2 may include one second micro lens MLZ2. The first sub-lens area SLS1 covering the first sub-pixel SPX1 may include three sub-micro lenses MLZ11 to MLZ13 respectively covering the three equal areas. The second micro lens MLZ2 and the three sub-micro lenses MLZ11 to MLZ13 may have the same shape and the same size. Therefore, in a similar manner to what has been discussed above, an amount by which each of the sub-micro lenses MLZ blocks the incident light to the second micro lens MLZ2 adjacent thereto may be reduced.

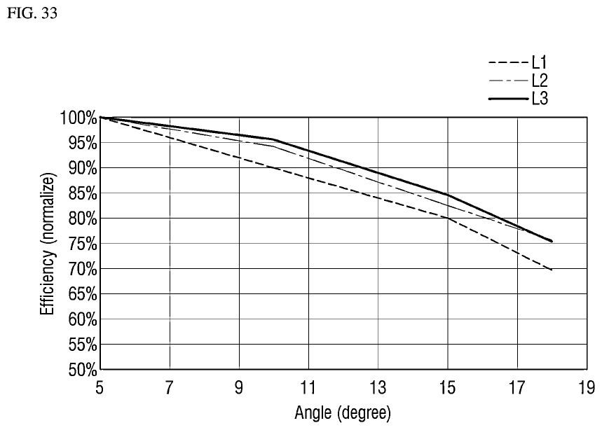

FIG. 33 is a graph showing a simulation result of light receiving efficiency of the second micro lens based on a viewing angle of each of lens arrays according to some example embodiments. In FIG. 33, a first line L1 represents the light receiving efficiency of the second micro lens when the lens array LSA_5 as illustrated in FIG. 19 and FIG. 20 is adopted. A second line L2 represents the light receiving efficiency of the second micro lens when the lens array LSA as shown in FIG. 9 is adopted. A third line L3 represents the light receiving efficiency of the second micro lens when the lens array LSA_C as shown in FIG. 10 and FIG. 11 is adopted. Based on FIG. 33, it may be identified that the third line L3 exhibits lower light-receiving efficiency of the obliquely incident light due to the larger vertical dimension of the summit of the first micro lens, while each of the first line L1 and the second line L2 exhibits higher light-receiving efficiency of the obliquely incident light due to the smaller vertical dimension of the summit of the first micro lens resulting from the depression or the hole.

The image sensor as described above is a kind of an optical sensor. The technical ideas according to the example embodiments may be applied to other types of sensors that detect an amount of incident light using a semiconductor, a fingerprint sensor, and/or a distance measurement sensor, etc. other than the image sensor.

The image sensing device 1 (or other circuitry, for example, control register block 1110, timing generator 1120, row driver 1130, pixel array PA, readout circuit 1150, ramp signal generator 1160, buffer 1170, logic chips CHP1, CHP2, CHP3) may include hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the example embodiments of the present disclosure have been described above with reference to the accompanying drawings, the present disclosure may not be limited to the example embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the example embodiments as described above are not restrictive but illustrative in all respects.

What is claimed is:

1. An image sensor comprising:
unit pixels, each of the unit pixels including a first sub-pixel and a second sub-pixel adjacent to the first sub-pixel in a plan view of the image sensor; and
a lens array including a first sub-lens area on the first sub-pixel of each unit pixel and a second sub-lens area on the second sub-pixel of each unit pixel,
the first sub-lens area including a first micro lens, and the second sub-lens area including a second micro lens, and
the first micro lens including a depression defined in a central area thereof.

2. The image sensor of claim 1, wherein a size of a planar shape of an outer boundary of the first micro lens is greater than a size of a planar shape of an outer boundary of the second micro lens.

3. The image sensor of claim 2, wherein a line extending along a summit of the first micro lens defines a closed curve in the plan view of the image sensor.

4. The image sensor of claim 3, wherein the first micro lens includes a first portion at one side around the depression and a second portion at the other side around the depression.

5. The image sensor of claim 4, wherein a vertical dimension of a summit of each of the first portion and the second portion is equal to or smaller than a vertical dimension of a summit of the second micro lens.

6. The image sensor of claim 4, wherein a shape of the first portion and a shape of the second portion are symmetrical with each other with respect to the depression.

7. The image sensor of claim 6, wherein curvature radii of cross sections of the first portion, the second portion, and the second micro lens are equal each other.

8. The image sensor of claim 4, wherein a summit outer area between an outer boundary and the summit of the first micro lens and a summit inner area between the summit and the depression have different radii of curvature.

9. The image sensor of claim 8, wherein the summit outer area has a same radius of curvature as a radius of curvature of the second micro lens.

10. The image sensor of claim 1, wherein
the lens array includes a base face which an outer boundary of the first micro lens and an outer boundary of the second micro lens are on,
the depression is on the base face.

11. The image sensor of claim 1, wherein the depression includes a hole, and a planar shape of the hole has a closed curve.

12. The image sensor of claim 11, wherein
the first micro lens includes a first portion at one side around the hole, and a second portion at the other side around the hole,
the first portion and the second portion are spaced apart from each other by a diameter of the hole, and
a cross section of the first portion, a cross section of the second portion, and a cross section of the second micro lens have a same shape and a same size.

13. The image sensor of claim 1, wherein the second micro lens is free of a depression in a central area thereof.

14. An image sensor comprising:
a plurality of unit pixels, each of the unit pixels including a first sub-pixel and a second sub-pixel adjacent to the first sub-pixel in a plan view of the image sensor, an area size of a second sub-pixel being smaller than an area size of the first sub-pixel in the plan view; and
a lens array including a first sub-lens area on the first sub-pixel of each unit pixel and a second sub-lens area on the second sub-pixel of each unit pixel,
the first sub-lens area including a first micro lens, and the second sub-lens area including a second micro lens, and
a first width of a first cross section of the first micro lens cut along a direction toward the second sub-pixel being smaller than a second width of a second cross section of the first micro lens cut along a direction toward another first micro lens adjacent thereto.

15. The image sensor of claim 14, wherein a spacing between the first micro lens on the first sub-pixel and the second sub-pixel adjacent thereto is greater than a spacing between the first micro lens on the first sub-pixel and another first sub-pixel adjacent thereto on the first sub-pixel.

16. The image sensor of claim 15, wherein the first micro lens includes a hole in an area thereof adjacent to the second micro lens.

17. The image sensor of claim 15, wherein
at least one of the plurality of unit pixels includes a first pixel covered with the first micro lens including a first hole at a center of the first micro lens, and
at least another of the plurality of unit pixels includes a second pixel covered with the first micro lens including a second hole positionally deviated from a center of the first micro lens.

18. The image sensor of claim 17, wherein
the second pixel is adjacent to the first pixel, and
the second hole is positionally deviated from the center of the first micro lens toward the first pixel.

19. An image sensor comprising:
a plurality of unit pixels, each of the unit pixels including a first sub-pixel and a second sub-pixel adjacent to the first sub-pixel in a plan view of the image sensor, an area size of a second sub-pixel being smaller than an area size of the first sub-pixel in the plan view; and
a lens array including a first sub-lens area on the first sub-pixel of each unit pixel and a second sub-lens area on the second sub-pixel of each unit pixel,
the first sub-lens area including a plurality of first micro lenses, and the second sub-lens area including a second micro lens, and
a number of the second micro lenses included in the second sub-lens area being smaller than a number of the plurality of first micro lenses included in the first sub-lens area.

20. The image sensor of claim 19, wherein the plurality of first micro lenses and the second micro lens have a same shape and a same size.
